(19) United States
(12) Patent Application Publication
(10) Pub. No.: US 2014/0100367 A1
(43) Pub. Date: Apr. 10, 2014

(54) NOVEL COMPOUNDS FOR ORGANIC ELECTRONIC MATERIAL AND ORGANIC ELECTROLUMINESCENT DEVICE USING THE SAME

(71) Applicants: Seok-Keun Yoon, Gyeonggi-do (KR); Hong-Yoep NA, Seoul (KR)

(72) Inventors: Seok-Keun Yoon, Gyeonggi-do (KR); Hong-Yoep NA, Seoul (KR)

(73) Assignee: Rohm and Haas Electronics Materials Korea Ltd., Chungcheongnam-do (KR)

(21) Appl. No.: 14/123,338

(22) PCT Filed: May 30, 2012
(86) PCT No.: PCT/KR2012/004239

§ 371 Date: Dec. 2, 2013

(30) Foreign Application Priority Data
May 30, 2011 (KR) 10-2011-0051173

(51) Int. Cl. H01L 51/00

(52) U.S. Cl. CPC H01L 51/0054; H01L 51/0072; H01L 51/0094; H01L 51/0052; H01L 51/0074; H01L 51/0073
USPC 544/229; 546/167; 544/284

(57) ABSTRACT

The present invention relates to a novel compound and an organic electroluminescent device containing the same. The compound according to the present invention can manufacture an organic electroluminescent device which has high luminous efficiency and a long operation lifetime.

### FIELD OF THE INVENTION

The present invention relates to novel compounds for organic electronic material and an organic electroluminescent device using the same.

### BACKGROUND OF THE INVENTION

An electroluminescent (EL) device is a self-light-emitting device which has advantages over other types of display devices in that it provides a wider viewing angle, a greater contrast ratio, and has a faster response time. An organic EL device was first developed by Eastman Kodak, by using small molecules such as aromatic diamines, and aluminum complexes as a material for forming a light-emitting layer [Appl. Phys. Lett. 51, 913, 1987].

The most important factor to determine luminous efficiency in an organic EL device is a light-emitting material. Until now, fluorescent materials have been widely used as a light-emitting material. However, in view of electroluminescent mechanisms, phosphorescent materials theoretically show four (4) times higher luminous efficiency than fluorescent materials. Iridium(III) complexes have been widely known as phosphorescent materials, including bis(2-(2′-benzothienyl)-pyridinato-N,C3′)iridium(acetylacetonate) [(acac)Ir(btp)₂], tris(2-phenylpyridine)iridium [Ir(ppy)₃] and bis(4,6-difluorophenylpyridinato-N,C2)picolinate iridium (Firpic) as red, green and blue materials, respectively. Especially, a lot of phosphorescent materials are being researched in Japan, Europe and U.S.A recently.

At present, 4,4′-N,N′-dicarbazol-biphenyl (CBP) is the most widely known as a host material for phosphorescent substances. Further, an organic EL device having high efficiency using bathocuproine (BCP) and aluminum(III)bis(2-methyl-8-quinolinate)(4-phenylphenolate) (BAlq) for a hole blocking layer is known, and Pioneer (Japan) et al. developed a high performance organic EL device employing a derivative of BAlq as a host material.

Though these phosphorous host materials provide good light-emitting characteristics, they have the following disadvantages: (1) Due to their low glass transition temperature and poor thermal stability, their degradation may occur during a high-temperature deposition process in a vacuum. (2) The power efficiency of an organic EL device is given by [(π/voltage)×current efficiency], and the power efficiency is inversely proportional to the voltage, and thus the power efficiency should be high in order to reduce power consumption. Although an organic EL device comprising phosphorescent materials provides higher current efficiency (cd/A) than one comprising fluorescent materials, when the conventional materials such as BAlq or CBP are used as phosphorescent host materials, a significantly high driving voltage is necessary compared to an organic EL device using a fluorescent material. Thus, there is no merit in terms of power efficiency (Im/W). (3) Further, the operation lifetime of an organic EL device is short and luminous efficiency is still required to be improved.

International Patent Publication No. WO 2006/049013 discloses compounds for organic electroluminescent materials having a condensed bicyclic group as a backbone structure. However, it does not disclose a compound of benzocarbazole having a nitrogen-containing condensed bicyclic group, which is substituted with an aromatic ring-fused heterocycloalkyl or cycloalkyl group, at the 9-position of the benzocarbazole.

### TECHNICAL PROBLEM

The objective of the present invention is to provide a compound for organic electronic material, which imparts high luminous efficiency and a long operation lifetime to a device, and having proper color coordination; and an organic electroluminescent device, which has high efficiency and a long lifetime, using the compound for organic electronic material.

### SOLUTION TO THE PROBLEM

The present inventors found that the above objective can be achieved by a compound represented by the following formula 1:

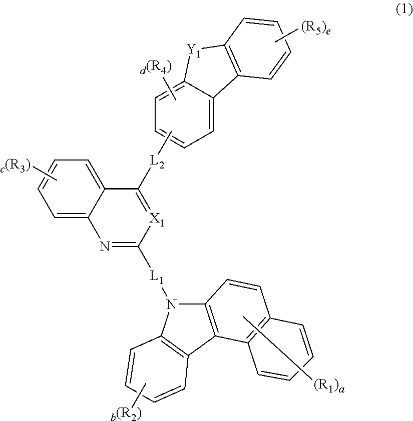

wherein

L₁ and L₂ each independently represent a single bond, a substituted or unsubstituted 3- to 30-membered heteroarylene group, a substituted or unsubstituted (C6-C30)arylene group, or a substituted or unsubstituted (C6-C30)cycloalkylene group;

X₁ represents CH or N;

Y₁ represents —O—, —S—, —CR₆R₇— or —NR₈—;

R₁ to R₅ each independently represent hydrogen, deuterium, a halogen, a substituted or unsubstituted (C1-C30)alkyl group, a substituted or unsubstituted (C6-C30)aryl group, a substituted or unsubstituted 3- to 30-membered heteroaryl group, a substituted or unsubstituted (C3-C30)cycloalkyl group, a substituted or unsubstituted 5- to 7-membered heterocycloalkyl group, a substituted or unsubstituted (C6-C30)aryl(C1-C30)alkyl group, —NR₁₁R₁₂, —SiR₁₃R₁₄R₁₅, —SR₁₆, —OR₁₇, a cyano group, a nitro group, or a hydroxyl group; or R4 and R5 each independently are linked to an adjacent substituent(s) to form a mono- or polycyclic, (C5-C30) alicyclic or aromatic ring whose carbon atom(s) may be replaced with at least one hetero atom selected from nitrogen, oxygen and sulfur;

R₆ to R₈ and R₁₁ to R₁₇ each independently represent hydrogen, deuterium, a halogen, a substituted or unsubstituted (C1-C30)alkyl group, a substituted or unsubstituted (C6-C30)aryl group, a substituted or unsubstituted 3- to 30-membered heteroaryl group, a substituted or unsubstituted 5- to 7-membered heterocycloalkyl group, or a substituted or unsubstituted (C3-C30)cycloalkyl group; or are linked to an adjacent substituent(s) to form a mono- or polycyclic, (C5-C30) alicyclic or aromatic ring whose carbon atom(s) may be replaced with at least one hetero atom selected from nitrogen, oxygen and sulfur;

a represents an integer of 1 to 6; where a is an integer of 2 or more, each of R₁ is the same or different;

b, c and e each independently represent an integer of 1 to 4; where b, c or e is an integer of 2 or more, each of R₂, each of R₃ or each of R₅ is the same or different;

d represents an integer of 1 to 3; where d is an integer of 2 or more, each of R₄ is the same or different; and

the heterocycloalkyl group and the heteroaryl(ene) group contain at least one hetero atom selected from B, N, O, S, P(═O), Si and P.

### ADVANTAGEOUS EFFECTS OF THE INVENTION

The compounds for organic electronic material according to the present invention can manufacture an organic electroluminescent device which has high luminous efficiency and a long operation lifetime.

### MODE FOR THE INVENTION

Hereinafter, the present invention will be described in detail. However, the following description is intended to explain the invention, and is not meant in any way to restrict the scope of the invention.

The present invention relates to a compound for organic electronic material represented by the above formula 1 and an organic electroluminescent device comprising the compound.

Herein, “(C1-C30)alkyl(ene)” is meant to be a linear or branched alkyl(ene) having 1 to 30 carbon atoms, in which the number of carbon atoms is preferably 1 to 20, more preferably 1 to 10, and includes methyl, ethyl, n-propyl, isopropyl, n-butyl, isobutyl, tert-butyl, etc.; “(C2-C30) alkenyl(ene)” is meant to be a linear or branched alkenyl(ene) having 2 to 30 carbon atoms, in which the number of carbon atoms is preferably 2 to 20, more preferably 2 to 10, and includes vinyl, 1-propenyl, 2-propenyl, 1-butenyl, 2-butenyl, 3-butenyl, 2-methylbut-2-enyl, etc.; “(C2-C30)alkynyl” is a linear or branched alkynyl having 2 to 30 carbon atoms, in which the number of carbon atoms is preferably 2 to 20, more preferably 2 to 10, and includes ethynyl, 1-propynyl, 2-propynyl, 1-butynyl, 2-butynyl, 3-butynyl, 1-methylpent-2-ynyl, etc.; “(C1-C30)alkoxy” is a linear or branched alkoxy having 1 to 30 carbon atoms, in which the number of carbon atoms is preferably 1 to 20, more preferably 1 to 10, and includes methoxy, ethoxy, propoxy, isopropoxy, 1-ethylpropoxy, etc.; “(C3-C30)cycloalkyl” is a mono- or polycyclic hydrocarbon having 3 to 30 carbon atoms, in which the number of carbon atoms is preferably 3 to 20, more preferably 3 to 7, and includes cyclopropyl, cyclobutyl, cyclopentyl, cyclohexyl, etc.; “(C6-C30)cycloalkylene” is one formed by removing a hydrogen from cycloalkyl having 6 to 30, preferably 6 to 20, more preferably 6 to 12 carbon atoms; “5- to 7-membered heterocycloalkyl” is a cycloalkyl having at least one heteroatom selected from B, N, O, S, P(═O), Si and P, preferably N, O and S, and 5 to 7 ring backbone atoms, and includes tetrahydrofurane, pyrrolidine, thiolan, tetrahydropyran, etc.; “(C6-C30)aryl(ene)” is a monocyclic or fused ring derived from an aromatic hydrocarbon having 6 to 30 carbon atoms, in which the number of carbon atoms is preferably 6 to 20, more preferably 6 to 12, and includes phenyl, biphenyl, terphenyl, naphthyl, fluorenyl, phenanthrenyl, anthracenyl, indenyl, triphenylenyl, pyrenyl, tetracenyl, perylenyl, chrysenyl, naphthacenyl, fluoranthenyl, etc.; “3- to 30-membered heteroaryl(ene)” is an aryl having at least one, preferably 1 to 4 heteroatom selected from the group consisting of B, N, O, S, P(═O), Si and P, and 3 to 30 ring backbone atoms; is a monocyclic ring or fused ring condensed with at least one benzene ring; has preferably 5 to 21, more preferably 5 to 12 ring backbone atoms; may be partially saturated; may be one formed by linking at least one heteroaryl or aryl group to a heteroaryl group via a single bond(s); and includes a monocyclic ring-type heteroaryl including furyl, thiophenyl, pyrrolyl, imidazolyl, pyrazolyl, thiazolyl, thiadiazolyl, isothiazolyl, isoxazolyl, oxazolyl, oxadiazolyl, triazinyl, tetrazinyl, triazolyl, tetrazolyl, furazanyl, pyridyl, pyrazinyl, pyrimidinyl, pyridazinyl, etc., and a fused ring-type heteroaryl including benzofuranyl, benzothiophenyl, isobenzofuranyl, dibenzofuranyl, dibenzothiophenyl, benzoimidazolyl, benzothiazolyl, benzoisothiazolyl, benzoisoxazolyl, benzoxazolyl, isoindolyl, indolyl, indazolyl, benzothiadiazolyl, quinolyl, isoquinolyl, cinnolinyl, quinazolinyl, quinoxalinyl, carbazolyl, phenoxazinyl, phenanthridinyl, benzodioxolyl, etc. Further, “Halogen” includes F, Cl, Br and I.

Substituents of the substituted alkyl(ene) group, the substituted aryl(ene) group, the substituted heteroaryl(ene) group, the substituted cycloalkyl(ene) group, the substituted heterocycloalkyl group, the substituted aralkyl group and the substituted alkenylene in L₁, L₂, R₁ to R₅, R₆ to R₈ and R₁₁ to R₁₇ groups each independently are at least one selected from the group consisting of deuterium, a halogen, a (C1-C30)alkyl group substituted or unsubstituted with a halogen, a (C6-C30)aryl group, a 3- to 30-membered heteroaryl group substituted or unsubstituted with a (C6-C30)aryl, a (C3-C30)cycloalkyl group, a 3- to 7-membered heterocycloalkyl group, a tri(C1-C30)alkylsilyl group, a tri(C6-C30)arylsilyl group, a di(C1-C30)alkyl (C6-C30)arylsilyl group, a (C1-C30)alkyl di(C6-C30)arylsilyl group, a (C2-C30)alkenyl group, a (C2-C30)alkynyl group, a cyano group, a carbazolyl group, a di(C1-C30)alkylamino group, a di(C6-C30)arylamino group, a (C1-C30)alkyl (C6-C30)arylamino group, a di(C6-C30)arylboronyl group, a di(C1-C30)alkylboronyl group, a (C1-C30)alkyl (C6-C30)arylboronyl group, a (C6-C30)aryl (C1-C30)alkyl group, a (C1-C30)alkyl (C6-C30)aryl group, a carboxyl group, a nitro group and a hydroxyl group.

In the above formula 1, L₁ and L₂ each independently represent a single bond, a 3- to 30-membered heteroarylene group, a (C6-C30)arylene group, or a (C6-C30)cycloalkylene group; X₁ represents CH or N; Y₁ represents —O—, —S—, —CR₆R₇— or —NR₈—; R₁ to R₅ each independently represent hydrogen, deuterium, a halogen, a (C1-C30)alkyl group, a (C6-C30)aryl group, a 3- to 30-membered heteroaryl group, a N-carbazolyl group, —NR₁₁R₁₂, or —SiR₁₃R₁₄R₁₅; or R₄ and R₅ each independently are linked to an adjacent substituent(s) to form a mono- or polycyclic, (C5-C30) alicyclic or aromatic ring whose carbon atom(s) may be replaced with at least one hetero atom selected from nitrogen, oxygen and sulfur; R₆ to R₈ each independently represent hydrogen, deuterium, a halogen, a (C1-C30)alkyl group, a (C6-C30)aryl group, or a 3- to 30-membered heteroaryl group; R₁₁ to R₁₅ each independently represent a (C1-C30)alkyl group, a (C6-C30)aryl group, or a 3- to 30-membered heteroaryl group; and the arylene group, the heteroarylene group and the cycloalkylene group in L₁ and L₂, and the alkyl group, the aryl group and the heteroaryl group in R₁ to R₅ and R₁₁ to R₁₅ each independently are substituted or unsubstituted with at least one selected from the group consisting of deuterium, a halogen, a (C1-C30)alkyl group substituted or unsubstituted with a halogen, a (C6-C30)aryl group, a (C1-C30)alkyl (C6-C30)aryl group, a 3- to 30-membered heteroaryl group substituted or unsubstituted with a (C6-C30)aryl, a (C3-C30)cycloalkyl group, and a (C6-C30)aryl (C1-C30)alkyl group.

L₁ and L₂ each independently are preferably a single bond, a substituted or unsubstituted (C6-C15)arylene group, or a substituted or unsubstituted (C6-C12)cycloalkyene group, and the substituent of the substituted arylene group is preferably a (C1-C6)alkyl group. L₁ and L₂ each independently are preferably a single bond, phenylene, naphthylene, biphenylene, terphenylene, anthrylene, indenylene, fluorenylene, phenanthrylene, triphenylenylene, pyrenylene, phenylenylene, chrysenylene, naphthasenylene, fluorantenyl, cyclopropylene, cyclobutylene, cyclopentylene, cyclohexylene, cycloheptylene, cyclooctylene, furylene, thiophenylene, pyrrolylene, imidazolylene, pyrazolylene, thiazolylene, thiadiazolylene, isothiazolylene, isoxazolylene, oxazolylene, oxadiazolylene, triazinylene, tetrazinylene, triazolylene, tetrazolylene, furazanylene, pyridylene, pyrazinylene, pyrimidinylene, pyridazinylene, benzofuranylene, benzothiophenylene, isobenzofuranylene, benzoimidazolylene, benzothiazolylene, benzoisothiazolylene, benzoisoxazolylene, benzooxazolylene, isoindolylene, indolylene, indazolylene, benzothiadiazolylene, quinolylene, isoquinolylene, cinnolinylene, quinazolinylene, quinoxalinylene, carbazolylene, phenanthridinylene, benzodioxolylene, dibenzofuranylene or dibenzothiophenylene.

In the above formula 1, X₁ represents CH or N, and Y₁ represents —O—, —S—, —CR₆R₇— or —NR₈—. When Y₁ is —CR₆R₇—, R₆ and R₇ each independently are preferably a substituted or unsubstituted (C1-C6)alkyl group. When Y₁ is —NR₈—, R₈ is preferably a substituted or unsubstituted (C6-C20)aryl group, or a substituted or unsubstituted 5- to 15-membered heteroaryl group. The substituent of the substituted aryl group is preferably selected from the group consisting of deuterium, a halogen, a (C1-C6)alkyl group and a (C6-C12)aryl group, and the substituent of the substituted heteroaryl group is preferably a (C6-C12)aryl group.

In the above formula 1, R₁ to R₅ each independently are preferably hydrogen, deuterium, a halogen, a substituted or unsubstituted (C6-C20)aryl group, a substituted or unsubstituted 5- to 15-membered heteroaryl group, —NR₁₁R₁₂ or —SiR₁₃R₁₄R₁₅; or R₄ or R₅ may be linked to an adjacent substituent(s) to form a mono- or polycyclic, (C5-C30) alicyclic or aromatic ring. In R₁ to R₅, the substituent of the substituted aryl group is preferably a (C1-C6)alkyl group. R₁₁ and R₁₂ each independently are preferably a substituted or unsubstituted (C6-C12)aryl group, and R₁₃ to R₁₅ each independently are preferably a substituted or unsubstituted (C1-C6)alkyl group, or a substituted or unsubstituted (C6-C12)aryl group. R₄ or R₅ preferably are linked to an adjacent substituent(s) to form an (C6-C12)aromatic ring.

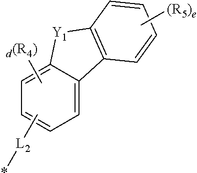

In the above formula 1, is selected from the following structures, but are not limited thereto:

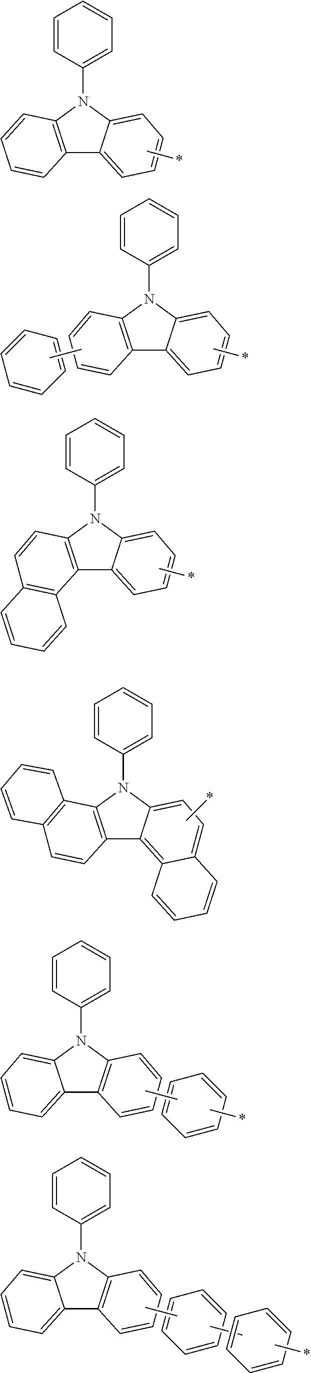

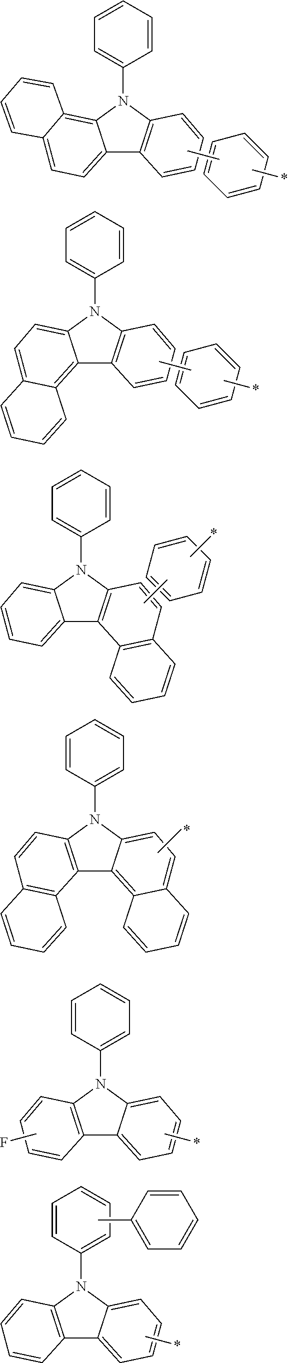

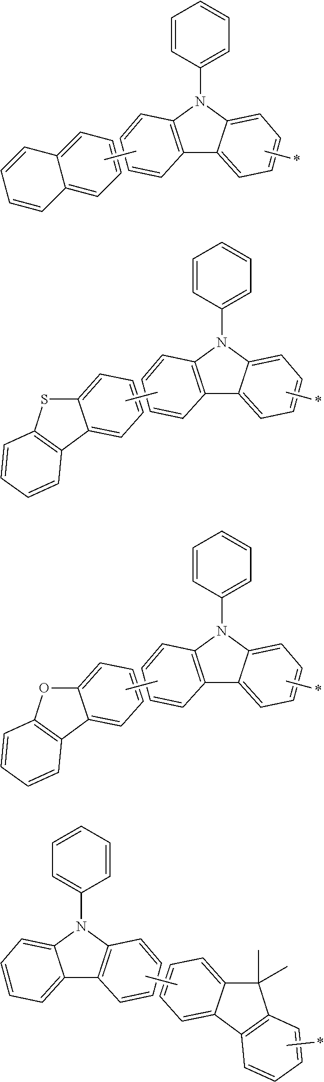

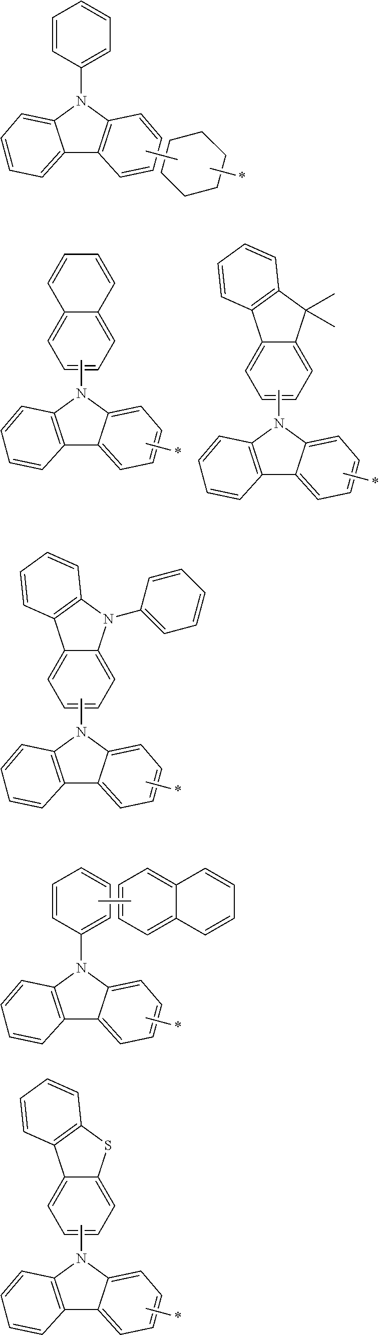

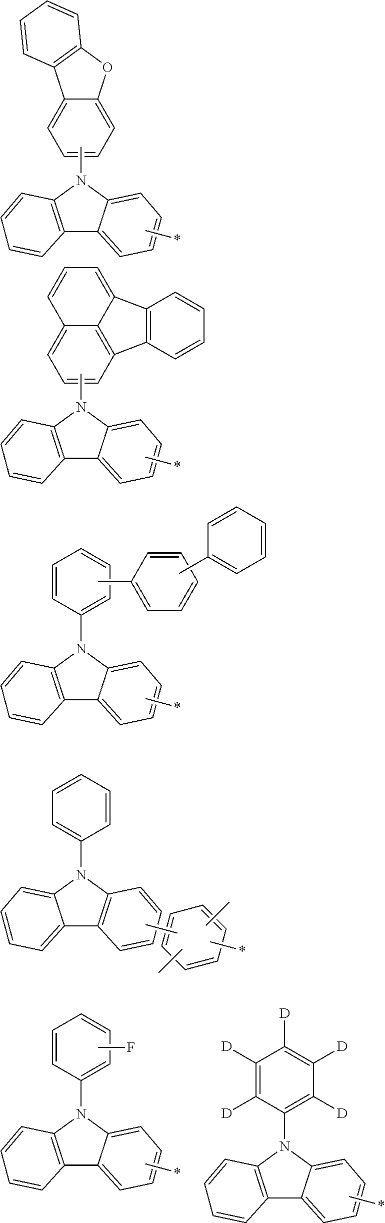

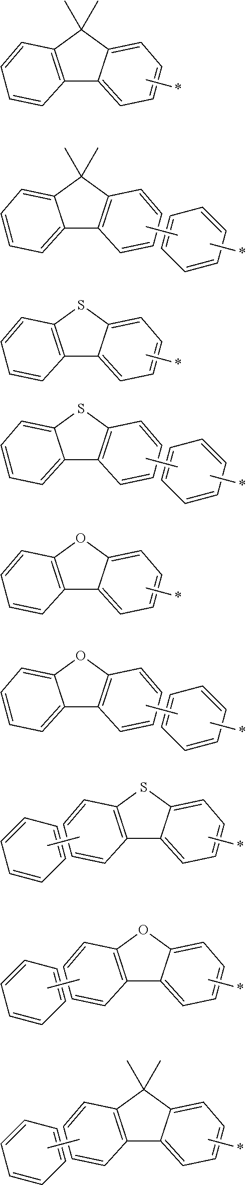

The representative compounds of the present invention include the following compounds:

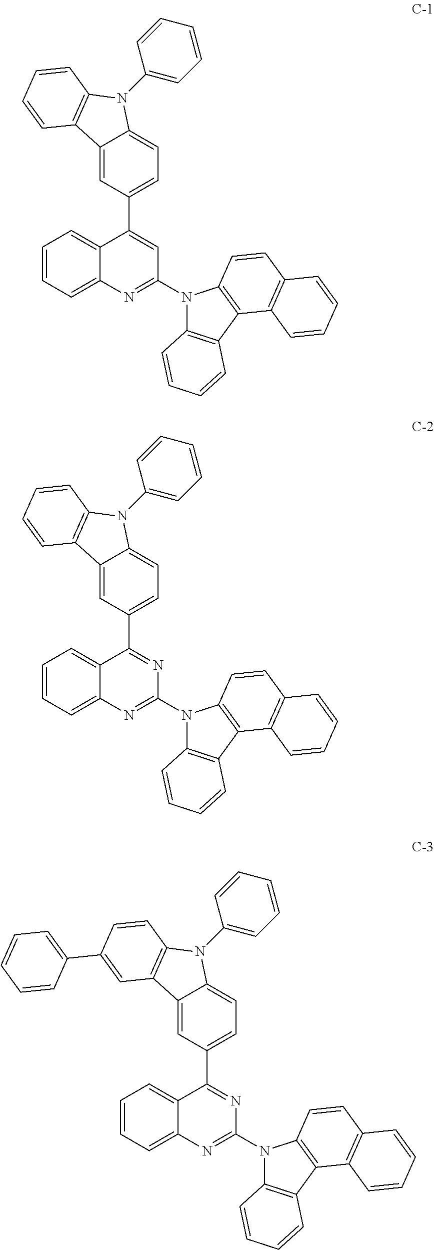 [SMILES: c1ccc(-n2c3ccccc3c3cc(-c4cc(-n5c6ccccc6c6c7ccccc7ccc65)nc5ccccc45)ccc32)cc1 ; c1ccc(-n2c3ccccc3c3cc(-c4nc(-n5c6ccccc6c6c7ccccc7ccc65)nc5ccccc45)ccc32)cc1 ; c1ccc(-c2ccc3c(c2)c2cc(-c4nc(-n5c6ccccc6c6c7ccccc7ccc65)nc5ccccc45)ccc2n3-c2ccccc2)cc1]

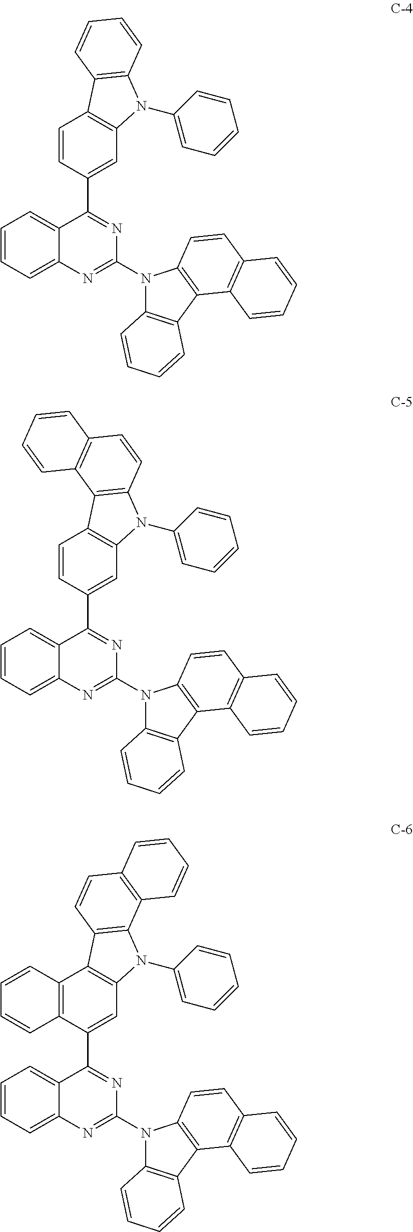

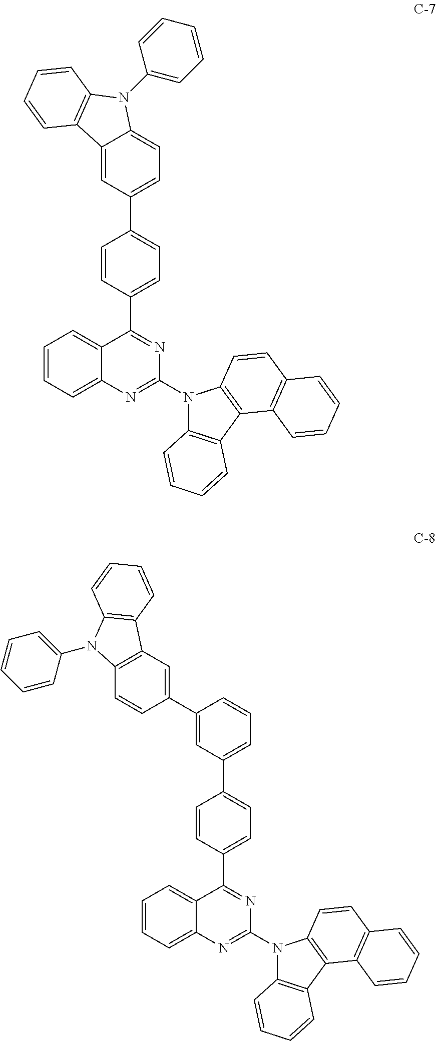 [SMILES: c1ccc(-n2c3ccccc3c3cc(-c4ccc(-c5nc(-n6c7ccccc7c7c8ccccc8ccc76)nc6ccccc56)cc4)ccc32)cc1 ; c1ccc(-n2c3ccccc3c3cc(-c4cccc(-c5ccc(-c6nc(-n7c8ccccc8c8c9ccccc9ccc87)nc7ccccc67)cc5)c4)ccc32)cc1]

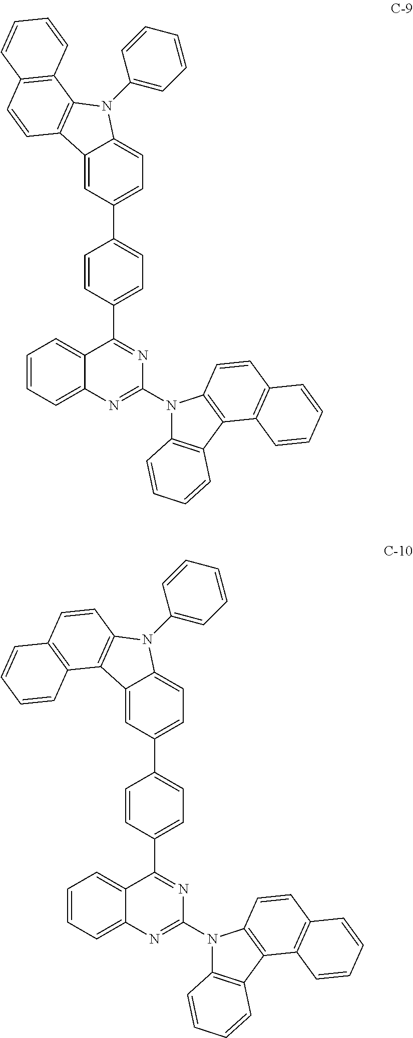 [SMILES: c1ccc(-n2c3ccc(-c4ccc(-c5nc(-n6c7ccccc7c7c8ccccc8ccc76)nc6ccccc56)cc4)cc3c3ccc4ccccc4c32)cc1 ; c1ccc(-n2c3ccc(-c4ccc(-c5nc(-n6c7ccccc7c7c8ccccc8ccc76)nc6ccccc56)cc4)cc3c3c4ccccc4ccc32)cc1]

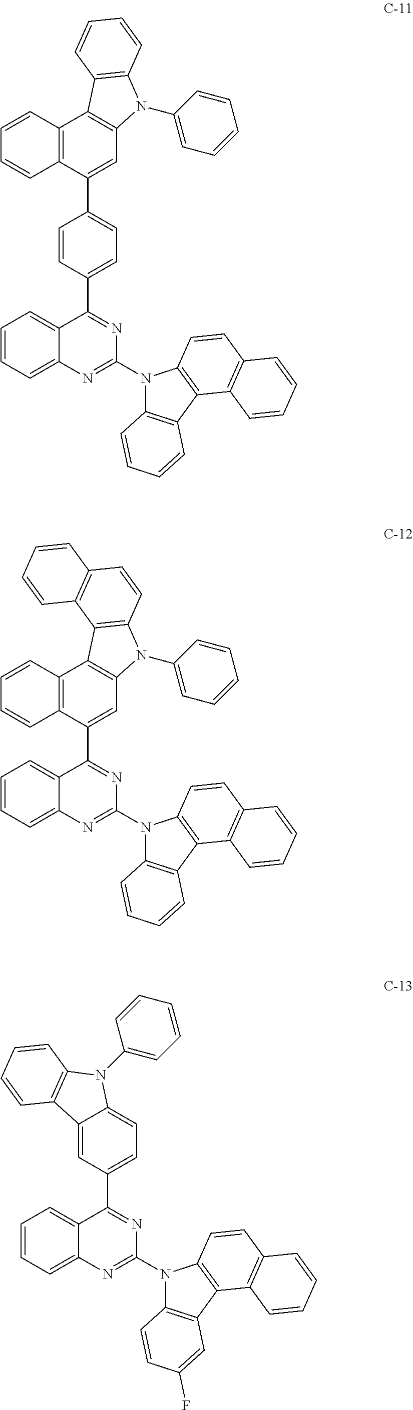 [SMILES: c1ccc(-n2c3ccccc3c3c4ccccc4c(-c4ccc(-c5nc(-n6c7ccccc7c7c8ccccc8ccc76)nc6ccccc56)cc4)cc32)cc1 ; c1ccc(-n2c3ccc4ccccc4c3c3c4ccccc4c(-c4nc(-n5c6ccccc6c6c7ccccc7ccc65)nc5ccccc45)cc32)cc1 ; Fc1ccc2c(c1)c1c3ccccc3ccc1n2-c1nc(-c2ccc3c(c2)c2ccccc2n3-c2ccccc2)c2ccccc2n1]

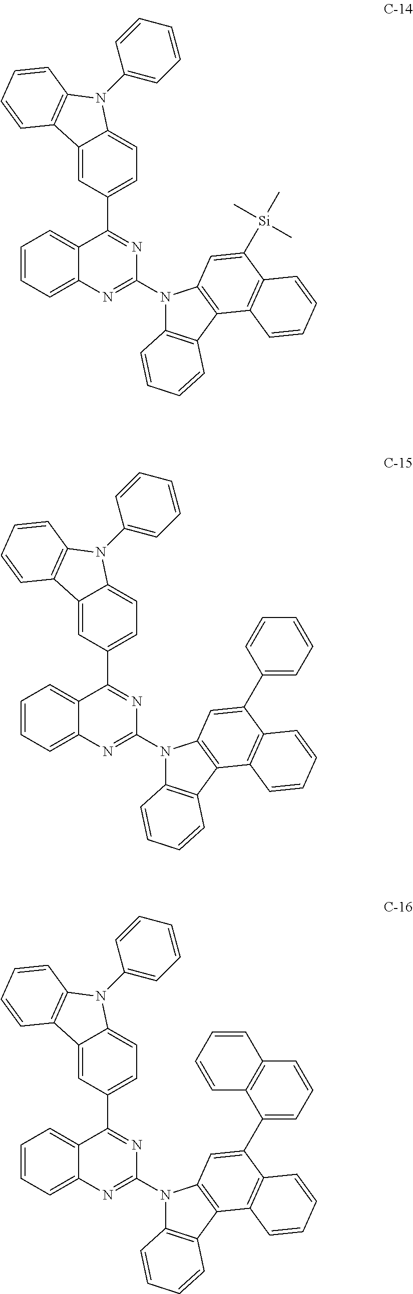 [SMILES: C[Si](C)(C)c1cc2c(c3ccccc13)c1ccccc1n2-c1nc(-c2ccc3c(c2)c2ccccc2n3-c2ccccc2)c2ccccc2n1 ; c1ccc(-c2cc3c(c4ccccc24)c2ccccc2n3-c2nc(-c3ccc4c(c3)c3ccccc3n4-c3ccccc3)c3ccccc3n2)cc1 ; c1ccc(-n2c3ccccc3c3cc(-c4nc(-n5c6ccccc6c6c7ccccc7c(-c7cccc8ccccc78)cc65)nc5ccccc45)ccc32)cc1]

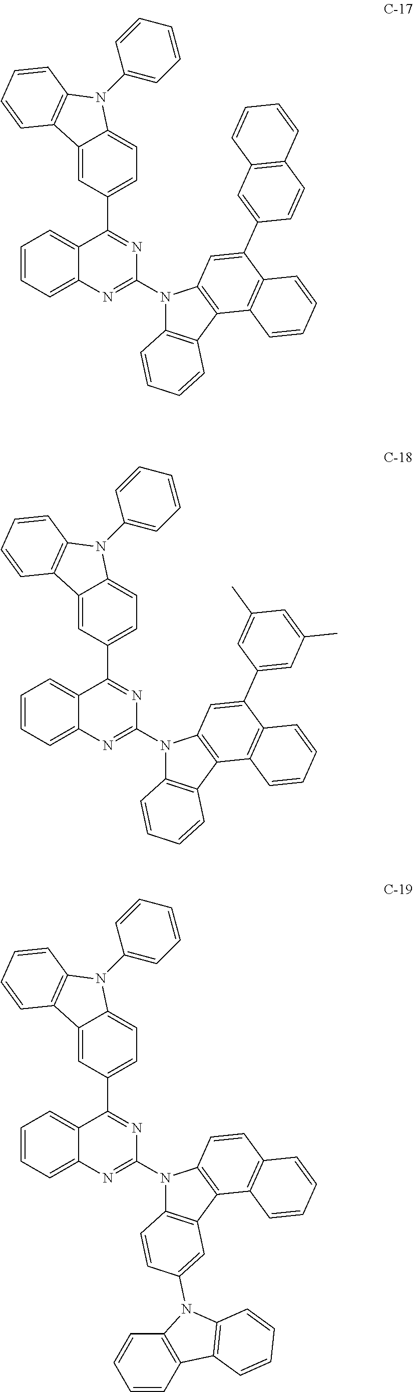 [SMILES: c1ccc(-n2c3ccccc3c3cc(-c4nc(-n5c6ccccc6c6c7ccccc7c(-c7ccc8ccccc8c7)cc65)nc5ccccc45)ccc32)cc1 ; Cc1cc(C)cc(-c2cc3c(c4ccccc24)c2ccccc2n3-c2nc(-c3ccc4c(c3)c3ccccc3n4-c3ccccc3)c3ccccc3n2)c1 ; c1ccc(-n2c3ccccc3c3cc(-c4nc(-n5c6ccc(-n7c8ccccc8c8ccccc87)cc6c6c7ccccc7ccc65)nc5ccccc45)ccc32)cc1]

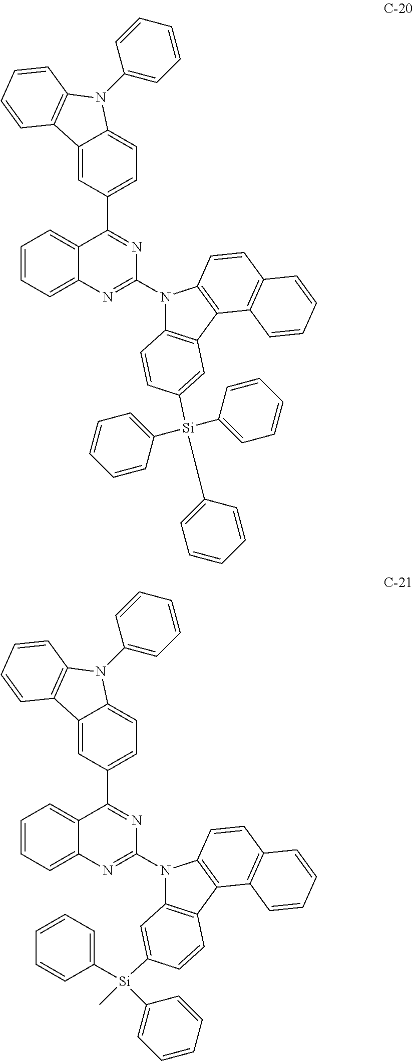 [SMILES: c1ccc(-n2c3ccccc3c3cc(-c4nc(-n5c6ccc([Si](c7ccccc7)(c7ccccc7)c7ccccc7)cc6c6c7ccccc7ccc65)nc5ccccc45)ccc32)cc1 ; C[Si](c1ccccc1)(c1ccccc1)c1ccc2c3c4ccccc4ccc3n(-c3nc(-c4ccc5c(c4)c4ccccc4n5-c4ccccc4)c4ccccc4n3)c2c1]

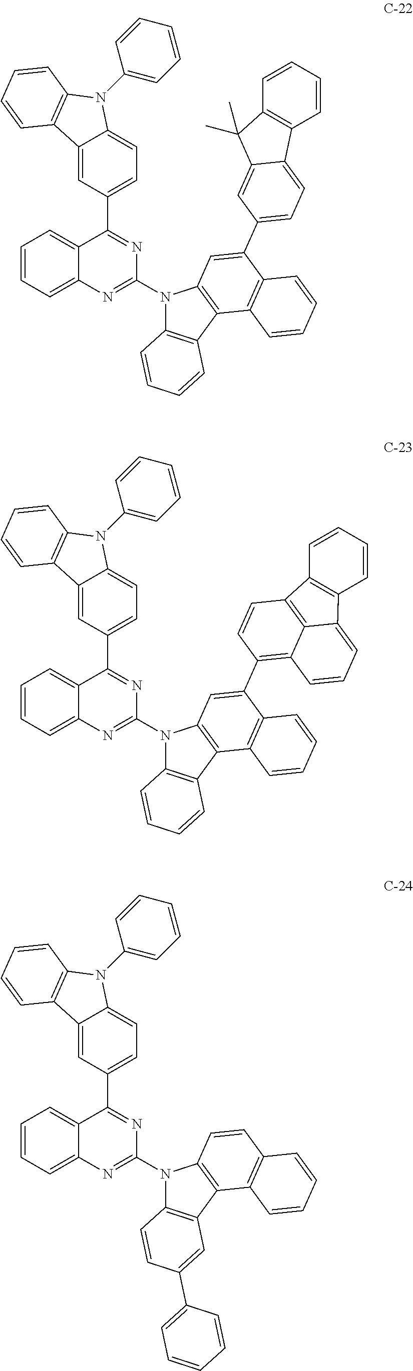 [SMILES: CC1(C)c2ccccc2-c2ccc(-c3cc4c(c5ccccc35)c3ccccc3n4-c3nc(-c4ccc5c(c4)c4ccccc4n5-c4ccccc4)c4ccccc4n3)cc21 ; c1ccc(-n2c3ccccc3c3cc(-c4nc(-n5c6ccccc6c6c7ccccc7c(-c7ccc8c9c(cccc79)-c7ccccc7-8)cc65)nc5ccccc45)ccc32)cc1 ; c1ccc(-c2ccc3c(c2)c2c4ccccc4ccc2n3-c2nc(-c3ccc4c(c3)c3ccccc3n4-c3ccccc3)c3ccccc3n2)cc1]

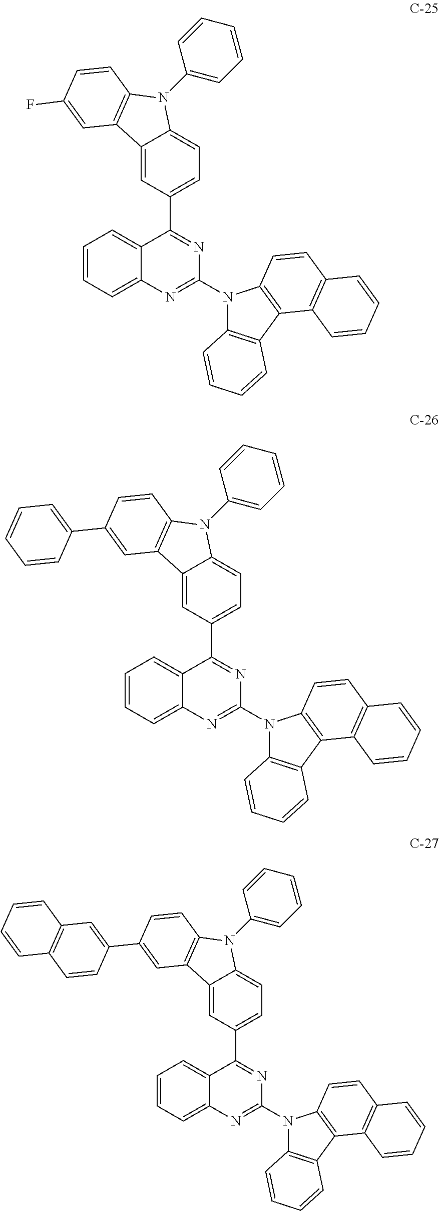 [SMILES: Fc1ccc2c(c1)c1cc(-c3nc(-n4c5ccccc5c5c6ccccc6ccc54)nc4ccccc34)ccc1n2-c1ccccc1 ; c1ccc(-c2ccc3c(c2)c2cc(-c4nc(-n5c6ccccc6c6c7ccccc7ccc65)nc5ccccc45)ccc2n3-c2ccccc2)cc1 ; c1ccc(-n2c3ccc(-c4ccc5ccccc5c4)cc3c3cc(-c4nc(-n5c6ccccc6c6c7ccccc7ccc65)nc5ccccc45)ccc32)cc1]

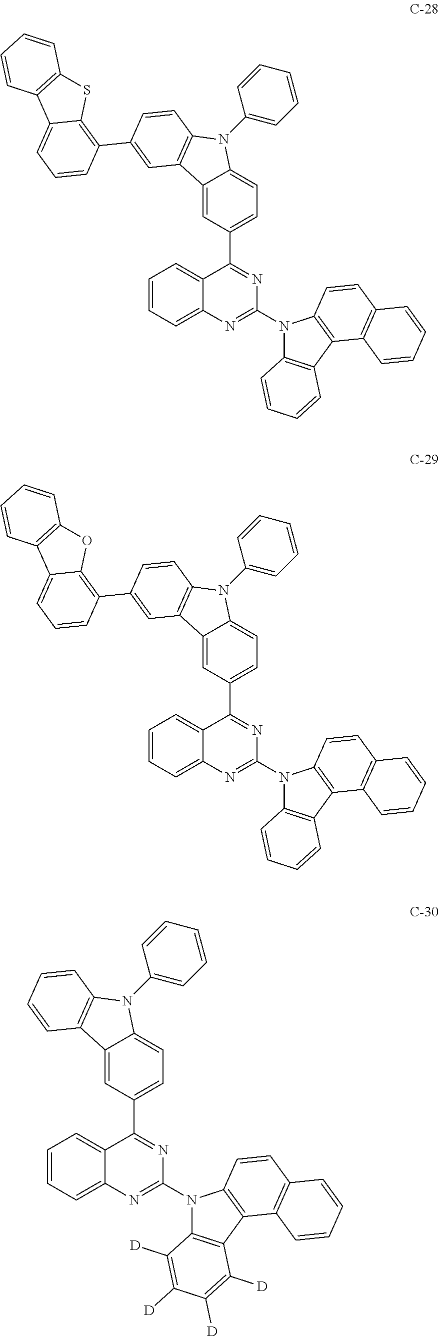 [SMILES: c1ccc(-n2c3ccc(-c4nc(-n5c6ccccc6c6c7ccccc7ccc65)nc5ccccc45)cc3c3cc(-c4cccc5c4sc4ccccc45)ccc32)cc1 ; c1ccc(-n2c3ccc(-c4nc(-n5c6ccccc6c6c7ccccc7ccc65)nc5ccccc45)cc3c3cc(-c4cccc5c4oc4ccccc45)ccc32)cc1 ; [2H]c1c([2H])c([2H])c2c(c1[2H])c1c3ccccc3ccc1n2-c1nc(-c2ccc3c(c2)c2ccccc2n3-c2ccccc2)c2ccccc2n1]

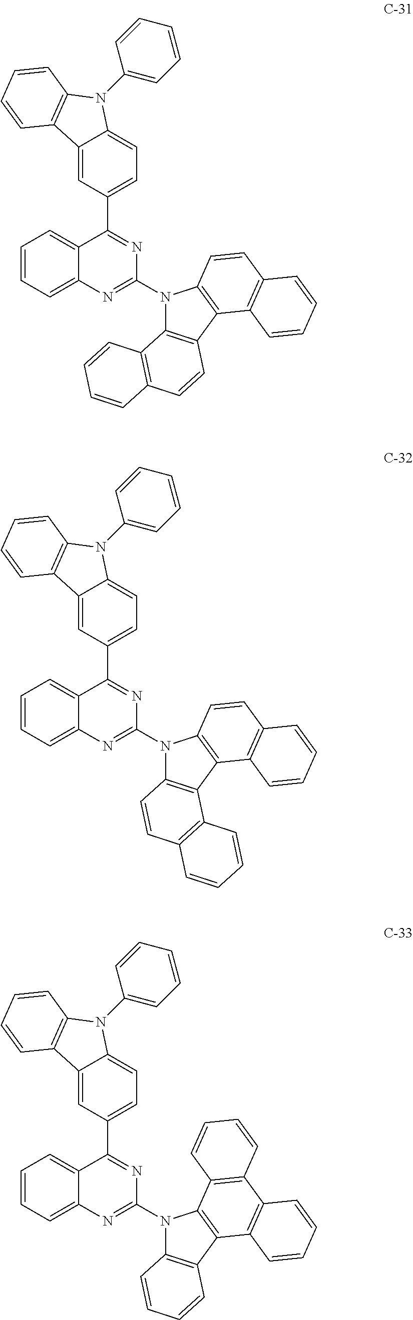 [SMILES: c1ccc(-n2c3ccccc3c3cc(-c4nc(-n5c6ccc7ccccc7c6c6ccc7ccccc7c65)nc5ccccc45)ccc32)cc1 ; c1ccc(-n2c3ccccc3c3cc(-c4nc(-n5c6ccc7ccccc7c6c6c7ccccc7ccc65)nc5ccccc45)ccc32)cc1 ; c1ccc(-n2c3ccccc3c3cc(-c4nc(-n5c6ccccc6c6c7ccccc7c7ccccc7c65)nc5ccccc45)ccc32)cc1]

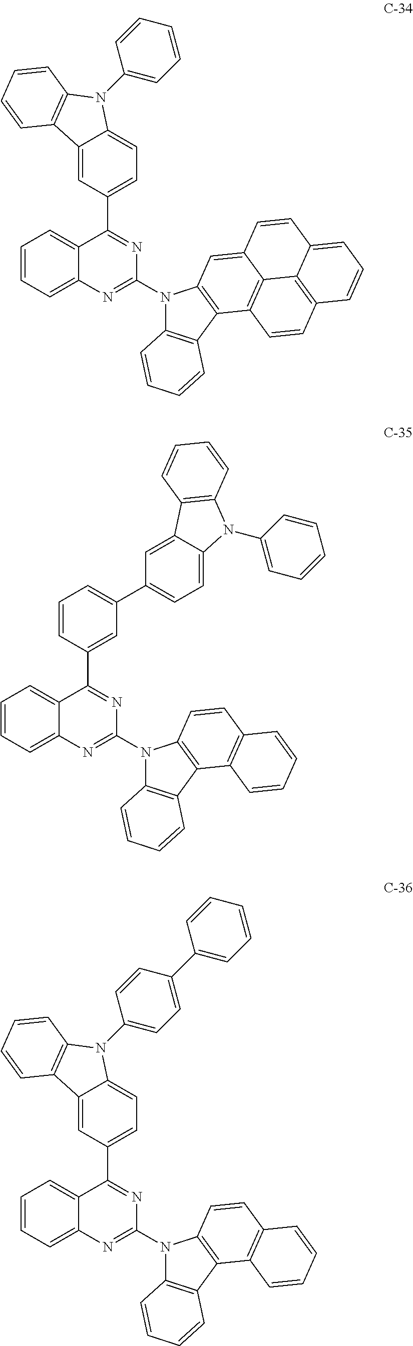 [SMILES: c1ccc(-n2c3ccccc3c3cc(-c4nc(-n5c6ccccc6c6c7ccc8cccc9ccc(cc65)c7c98)nc5ccccc45)ccc32)cc1 ; c1ccc(-n2c3ccccc3c3cc(-c4cccc(-c5nc(-n6c7ccccc7c7c8ccccc8ccc76)nc6ccccc56)c4)ccc32)cc1 ; c1ccc(-c2ccc(-n3c4ccccc4c4cc(-c5nc(-n6c7ccccc7c7c8ccccc8ccc76)nc6ccccc56)ccc43)cc2)cc1]

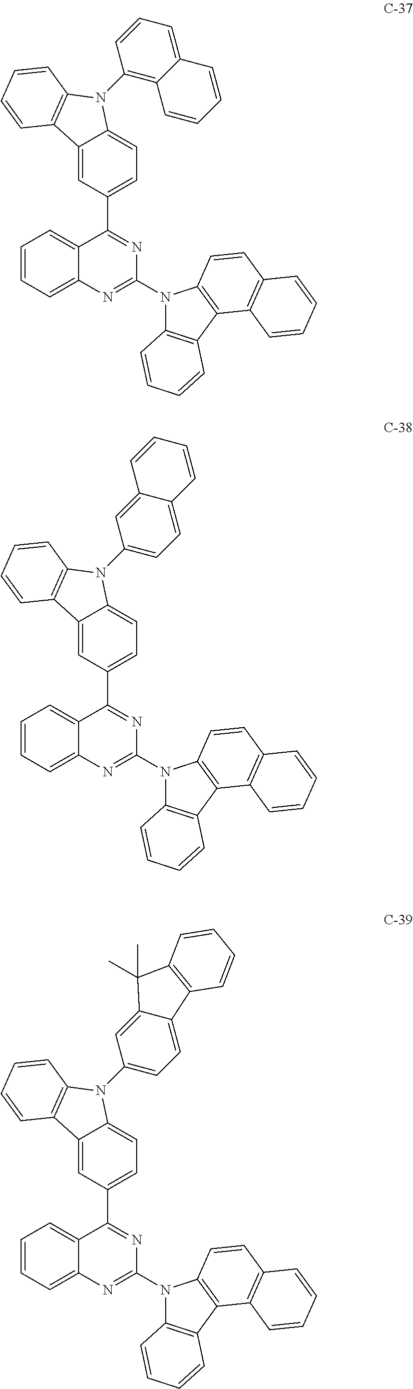 [SMILES: c1ccc2c(-n3c4ccccc4c4cc(-c5nc(-n6c7ccccc7c7c8ccccc8ccc76)nc6ccccc56)ccc43)cccc2c1 ; c1ccc2cc(-n3c4ccccc4c4cc(-c5nc(-n6c7ccccc7c7c8ccccc8ccc76)nc6ccccc56)ccc43)ccc2c1 ; CC1(C)c2ccccc2-c2ccc(-n3c4ccccc4c4cc(-c5nc(-n6c7ccccc7c7c8ccccc8ccc76)nc6ccccc56)ccc43)cc21]

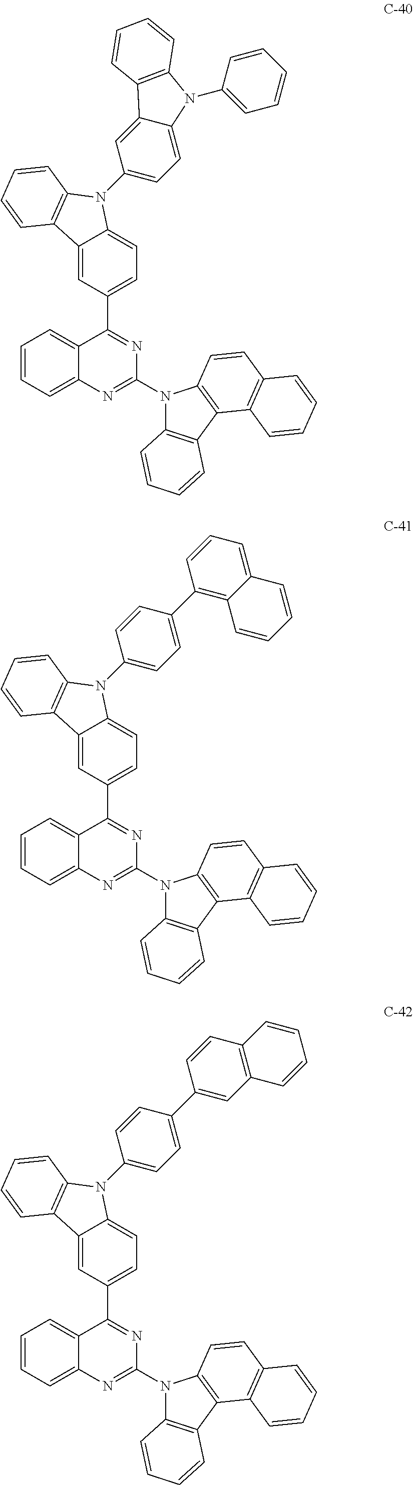 [SMILES: c1ccc(-n2c3ccccc3c3cc(-n4c5ccccc5c5cc(-c6nc(-n7c8ccccc8c8c9ccccc9ccc87)nc7ccccc67)ccc54)ccc32)cc1 ; c1ccc2c(-c3ccc(-n4c5ccccc5c5cc(-c6nc(-n7c8ccccc8c8c9ccccc9ccc87)nc7ccccc67)ccc54)cc3)cccc2c1 ; c1ccc2cc(-c3ccc(-n4c5ccccc5c5cc(-c6nc(-n7c8ccccc8c8c9ccccc9ccc87)nc7ccccc67)ccc54)cc3)ccc2c1]

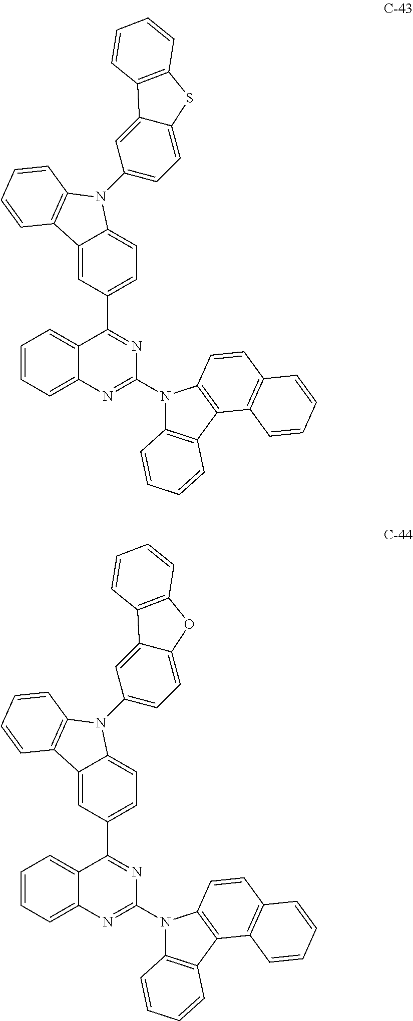 [SMILES: c1ccc2c(c1)ccc1c2c2ccccc2n1-c1nc(-c2ccc3c(c2)c2ccccc2n3-c2ccc3sc4ccccc4c3c2)c2ccccc2n1 ; c1ccc2c(c1)ccc1c2c2ccccc2n1-c1nc(-c2ccc3c(c2)c2ccccc2n3-c2ccc3oc4ccccc4c3c2)c2ccccc2n1]

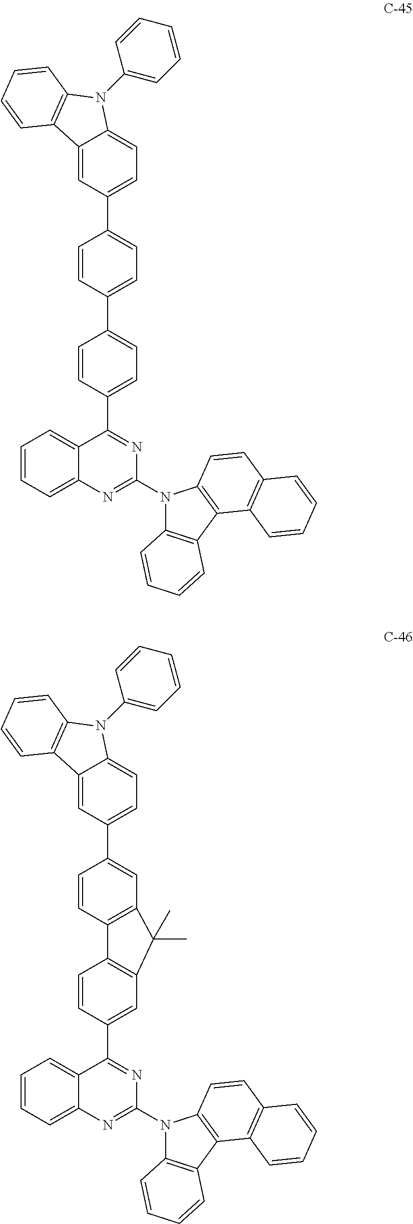 [SMILES: c1ccc(-n2c3ccccc3c3cc(-c4ccc(-c5ccc(-c6nc(-n7c8ccccc8c8c9ccccc9ccc87)nc7ccccc67)cc5)cc4)ccc32)cc1 ; CC1(C)c2cc(-c3ccc4c(c3)c3ccccc3n4-c3ccccc3)ccc2-c2ccc(-c3nc(-n4c5ccccc5c5c6ccccc6ccc54)nc4ccccc34)cc21]

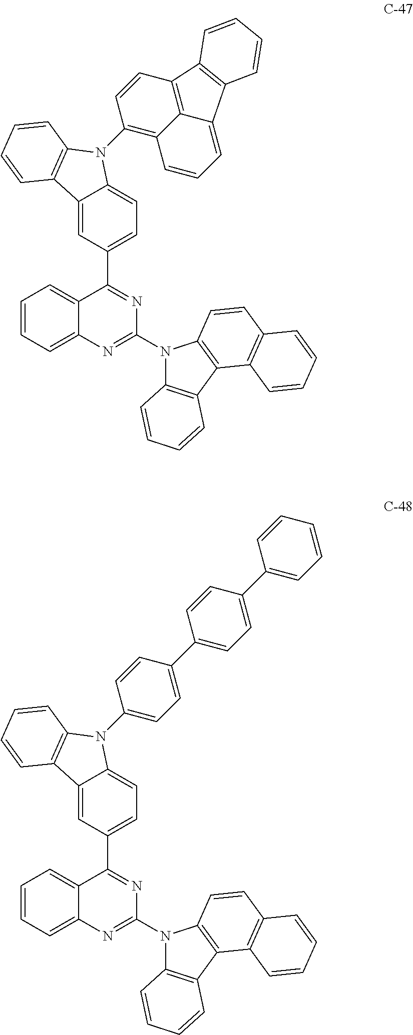 [SMILES: c1ccc2c(c1)-c1cccc3c(-n4c5ccccc5c5cc(-c6nc(-n7c8ccccc8c8c9ccccc9ccc87)nc7ccccc67)ccc54)ccc-2c13 ; c1ccc(-c2ccc(-c3ccc(-n4c5ccccc5c5cc(-c6nc(-n7c8ccccc8c8c9ccccc9ccc87)nc7ccccc67)ccc54)cc3)cc2)cc1]

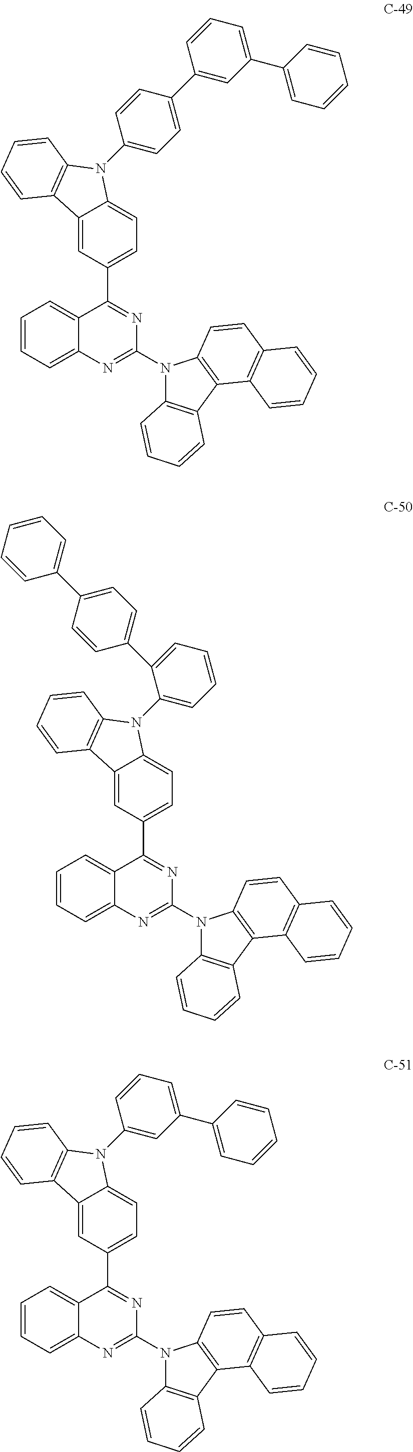 [SMILES: c1ccc(-c2cccc(-c3ccc(-n4c5ccccc5c5cc(-c6nc(-n7c8ccccc8c8c9ccccc9ccc87)nc7ccccc67)ccc54)cc3)c2)cc1 ; c1ccc(-c2ccc(-c3ccccc3-n3c4ccccc4c4cc(-c5nc(-n6c7ccccc7c7c8ccccc8ccc76)nc6ccccc56)ccc43)cc2)cc1 ; c1ccc(-c2cccc(-n3c4ccccc4c4cc(-c5nc(-n6c7ccccc7c7c8ccccc8ccc76)nc6ccccc56)ccc43)c2)cc1]

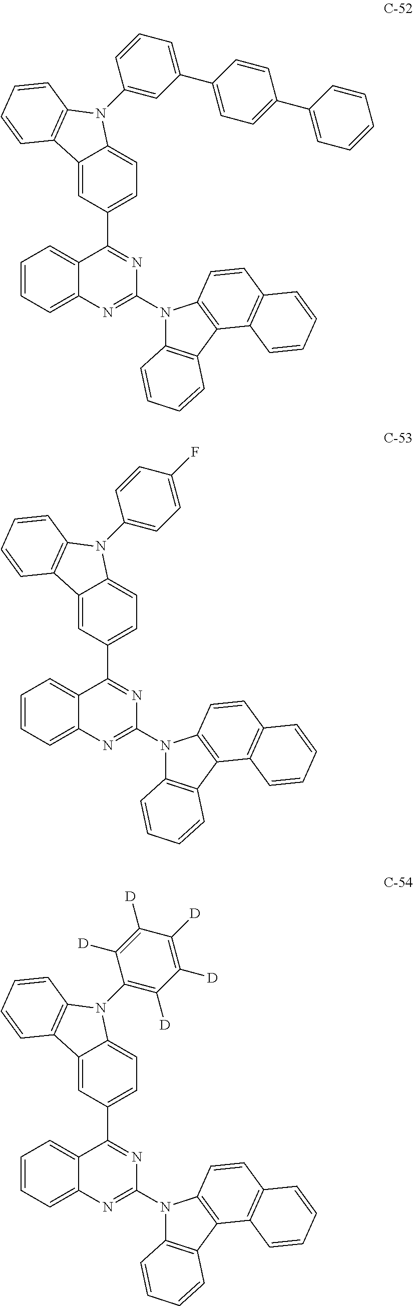

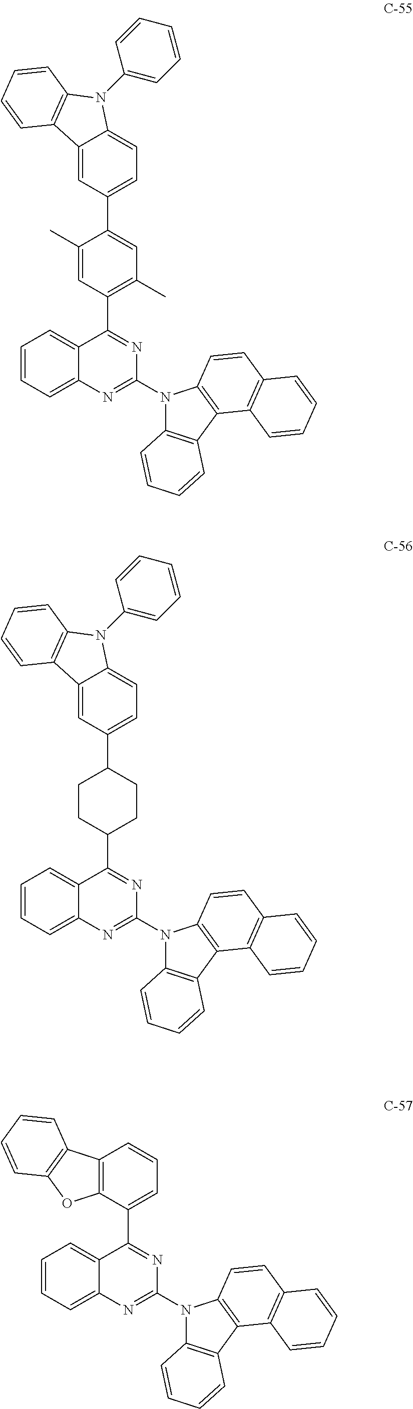 [SMILES: Cc1cc(-c2nc(-n3c4ccccc4c4c5ccccc5ccc43)nc3ccccc23)c(C)cc1-c1ccc2c(c1)c1ccccc1n2-c1ccccc1 ; c1ccc(-n2c3ccccc3c3cc(C4CCC(c5nc(-n6c7ccccc7c7c8ccccc8ccc76)nc6ccccc56)CC4)ccc32)cc1 ; c1ccc2c(c1)ccc1c2c2ccccc2n1-c1nc(-c2cccc3c2oc2ccccc23)c2ccccc2n1]

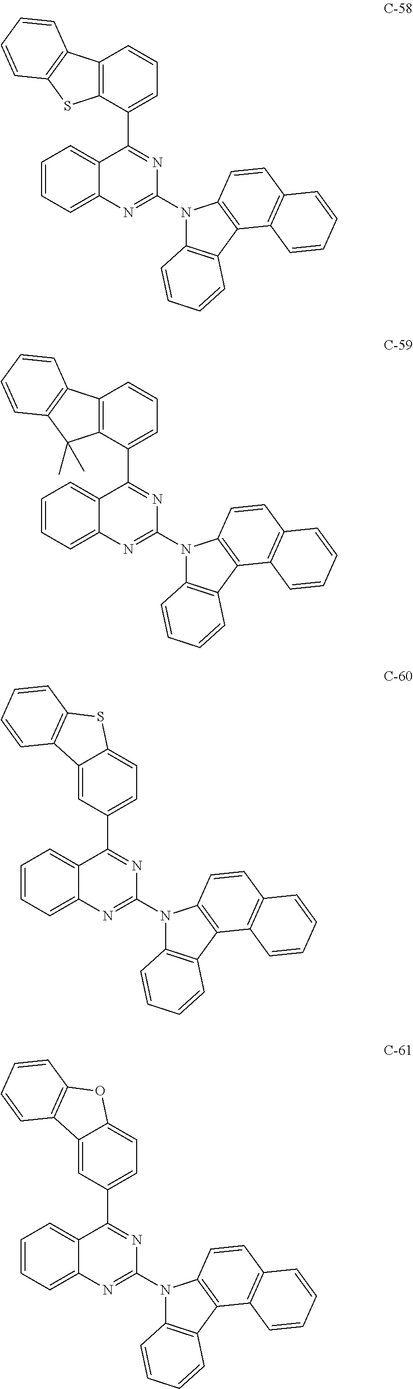 [SMILES: c1ccc2c(c1)ccc1c2c2ccccc2n1-c1nc(-c2cccc3c2sc2ccccc23)c2ccccc2n1 ; CC1(C)c2ccccc2-c2cccc(-c3nc(-n4c5ccccc5c5c6ccccc6ccc54)nc4ccccc34)c21 ; c1ccc2c(c1)ccc1c2c2ccccc2n1-c1nc(-c2ccc3sc4ccccc4c3c2)c2ccccc2n1 ; c1ccc2c(c1)ccc1c2c2ccccc2n1-c1nc(-c2ccc3oc4ccccc4c3c2)c2ccccc2n1]

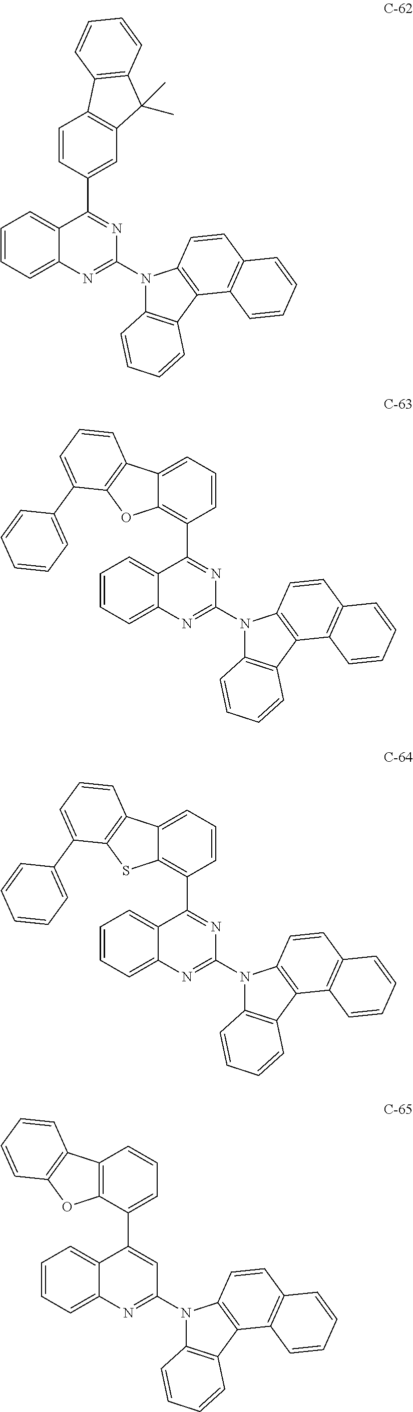 [SMILES: CC1(C)c2ccccc2-c2ccc(-c3nc(-n4c5ccccc5c5c6ccccc6ccc54)nc4ccccc34)cc21 ; c1ccc(-c2cccc3c2oc2c(-c4nc(-n5c6ccccc6c6c7ccccc7ccc65)nc5ccccc45)cccc23)cc1 ; c1ccc(-c2cccc3c2sc2c(-c4nc(-n5c6ccccc6c6c7ccccc7ccc65)nc5ccccc45)cccc23)cc1 ; c1ccc2c(c1)ccc1c2c2ccccc2n1-c1cc(-c2cccc3c2oc2ccccc23)c2ccccc2n1]

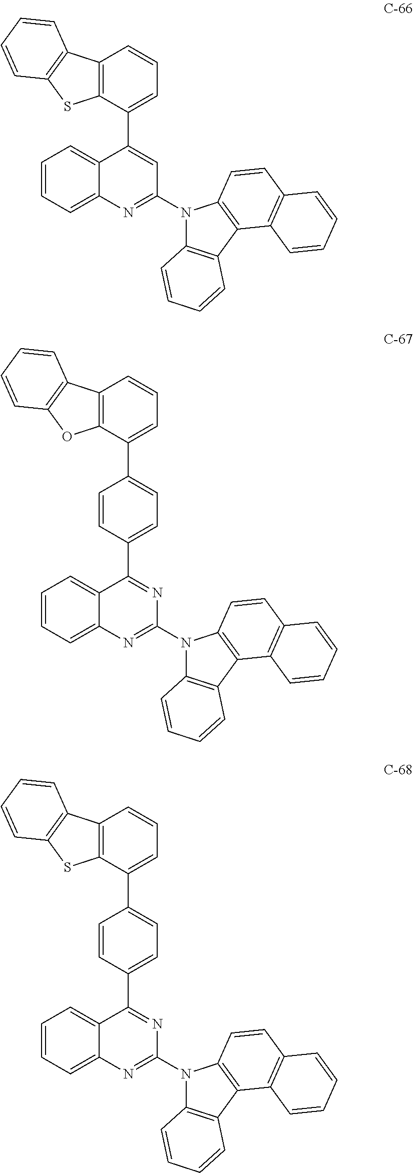 [SMILES: c1ccc2c(c1)ccc1c2c2ccccc2n1-c1cc(-c2cccc3c2sc2ccccc23)c2ccccc2n1 ; c1ccc2c(c1)ccc1c2c2ccccc2n1-c1nc(-c2ccc(-c3cccc4c3oc3ccccc34)cc2)c2ccccc2n1 ; c1ccc2c(c1)ccc1c2c2ccccc2n1-c1nc(-c2ccc(-c3cccc4c3sc3ccccc34)cc2)c2ccccc2n1]

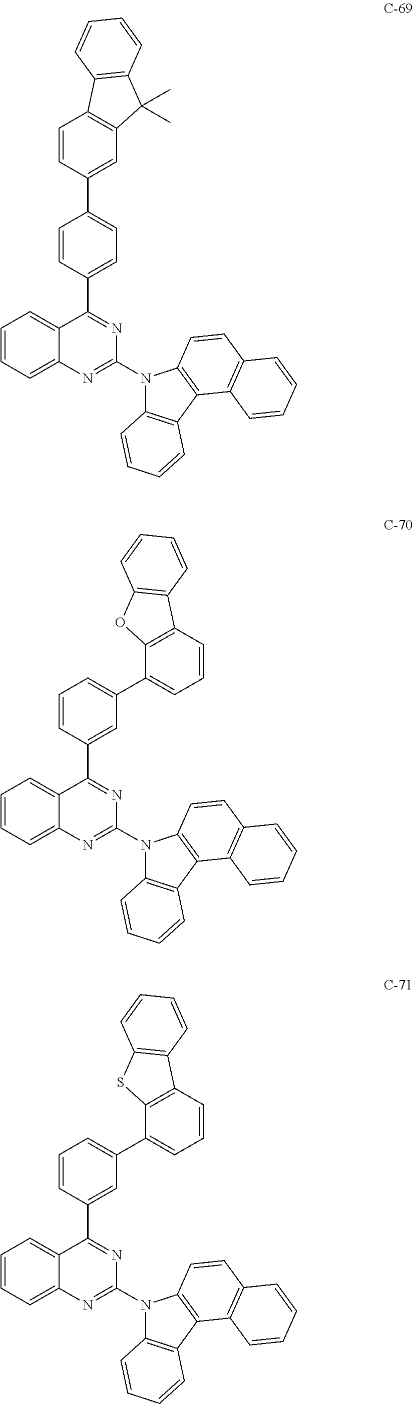 [SMILES: CC1(C)c2ccccc2-c2ccc(-c3ccc(-c4nc(-n5c6ccccc6c6c7ccccc7ccc65)nc5ccccc45)cc3)cc21 ; c1cc(-c2nc(-n3c4ccccc4c4c5ccccc5ccc43)nc3ccccc23)cc(-c2cccc3c2oc2ccccc23)c1 ; c1cc(-c2nc(-n3c4ccccc4c4c5ccccc5ccc43)nc3ccccc23)cc(-c2cccc3c2sc2ccccc23)c1]

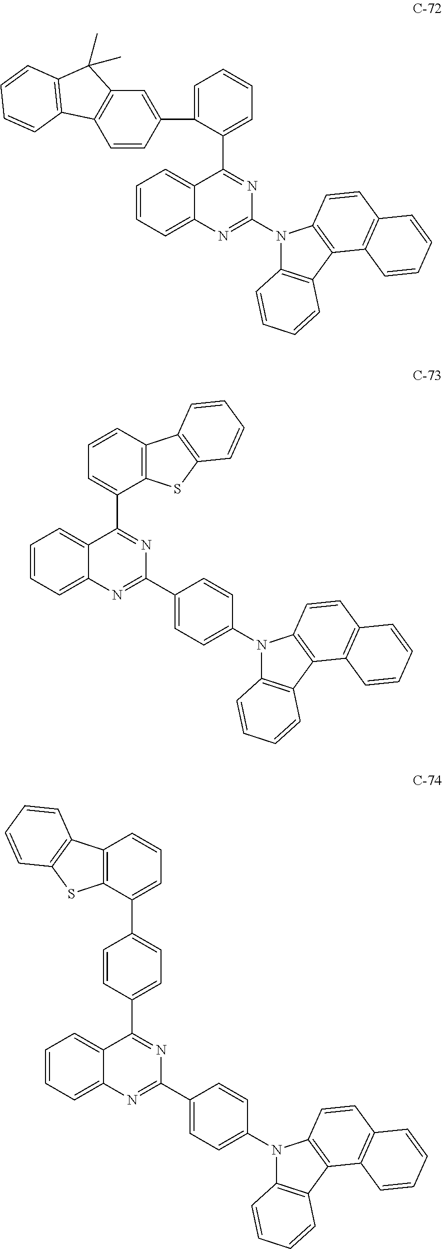 [SMILES: CC1(C)c2ccccc2-c2ccc(-c3ccccc3-c3nc(-n4c5ccccc5c5c6ccccc6ccc54)nc4ccccc34)cc21 ; c1ccc2c(c1)ccc1c2c2ccccc2n1-c1ccc(-c2nc(-c3cccc4c3sc3ccccc34)c3ccccc3n2)cc1 ; c1ccc2c(c1)ccc1c2c2ccccc2n1-c1ccc(-c2nc(-c3ccc(-c4cccc5c4sc4ccccc45)cc3)c3ccccc3n2)cc1]

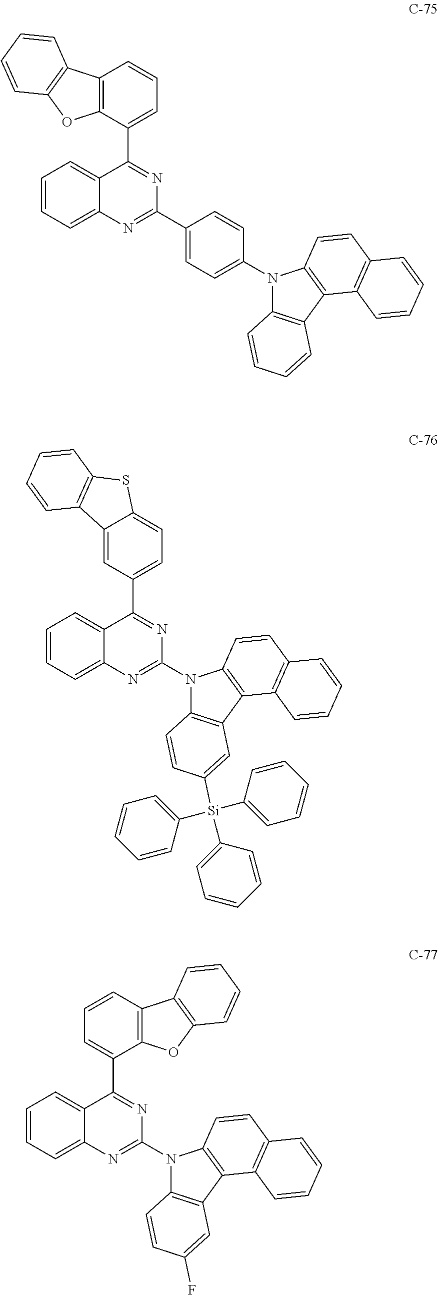 [SMILES: c1ccc2c(c1)ccc1c2c2ccccc2n1-c1ccc(-c2nc(-c3cccc4c3oc3ccccc34)c3ccccc3n2)cc1 ; c1ccc([Si](c2ccccc2)(c2ccccc2)c2ccc3c(c2)c2c4ccccc4ccc2n3-c2nc(-c3ccc4sc5ccccc5c4c3)c3ccccc3n2)cc1 ; Fc1ccc2c(c1)c1c3ccccc3ccc1n2-c1nc(-c2cccc3c2oc2ccccc23)c2ccccc2n1]

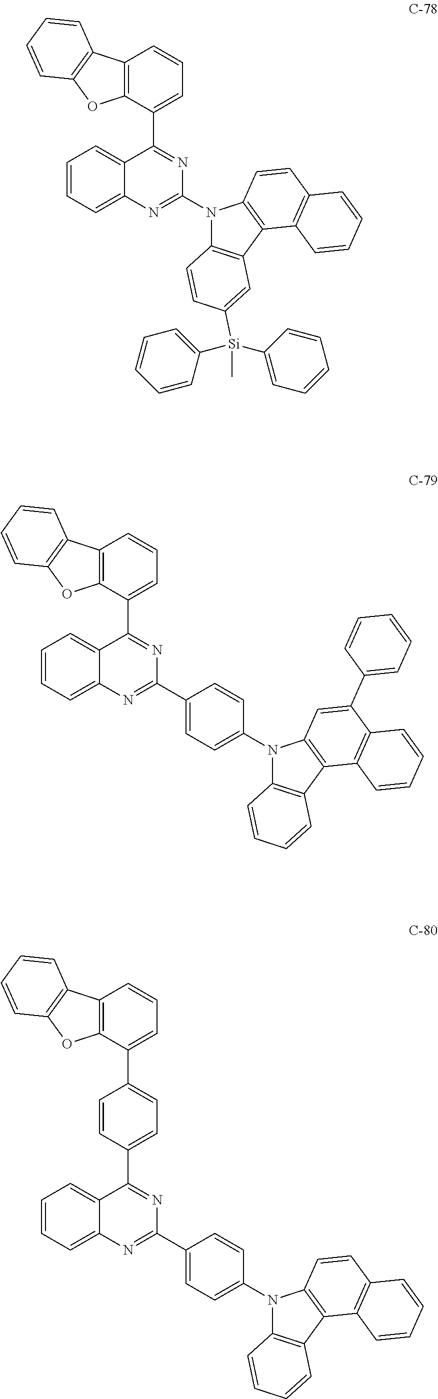 [SMILES: C[Si](c1ccccc1)(c1ccccc1)c1ccc2c(c1)c1c3ccccc3ccc1n2-c1nc(-c2cccc3c2oc2ccccc23)c2ccccc2n1 ; c1ccc(-c2cc3c(c4ccccc24)c2ccccc2n3-c2ccc(-c3nc(-c4cccc5c4oc4ccccc45)c4ccccc4n3)cc2)cc1 ; c1ccc2c(c1)ccc1c2c2ccccc2n1-c1ccc(-c2nc(-c3ccc(-c4cccc5c4oc4ccccc45)cc3)c3ccccc3n2)cc1]

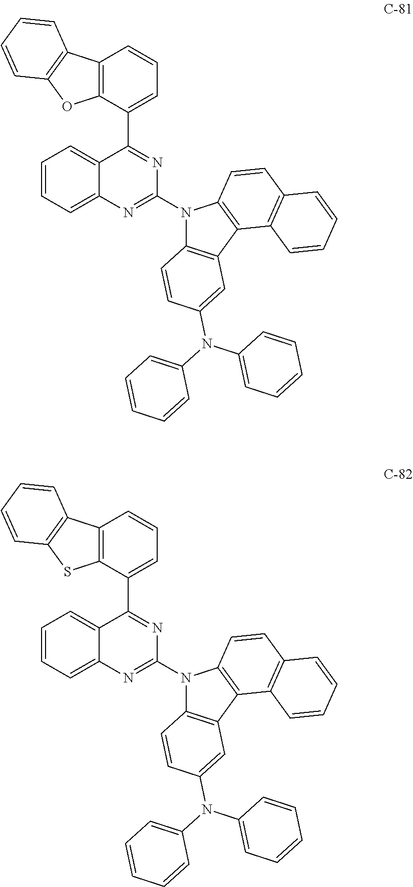 [SMILES: c1ccc(N(c2ccccc2)c2ccc3c(c2)c2c4ccccc4ccc2n3-c2nc(-c3cccc4c3oc3ccccc34)c3ccccc3n2)cc1 ; c1ccc(N(c2ccccc2)c2ccc3c(c2)c2c4ccccc4ccc2n3-c2nc(-c3cccc4c3sc3ccccc34)c3ccccc3n2)cc1]

The compounds for organic electronic materials according to the present invention can be prepared according to the following reaction scheme 1.

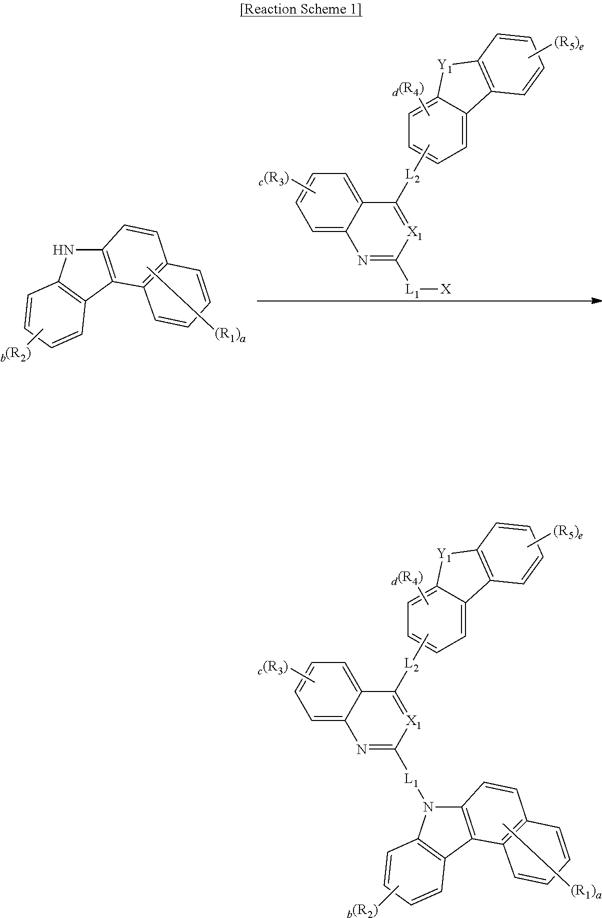

wherein R₁ to R₅, Y₁, X₁, L₁, L₂, a, b, c, d and e are as defined in formula 1 above, and X represents a halogen.

In addition, the present invention provides an organic electroluminescent device comprising the compound of formula 1. The organic electroluminescent device comprises a first electrode, a second electrode, and at least one organic layer between the first and second electrodes. The organic layer comprises at least one compound of formula 1 according to the present invention. Further, the organic layer comprises a light-emitting layer in which the compound of formula 1 is comprised as a host material.

In addition, a phosphorescent dopant, which is used for an organic electroluminescent device together with the host material according to the present invention, may be selected from compounds represented by the following formula 2:

M1 L¹⁰¹ L¹⁰² L¹⁰³ (2)

wherein M¹ is selected from the group consisting of Ir, Pt, Pd and Os; L¹⁰¹, L¹⁰² and L¹⁰³ are each independently selected from the following structures:

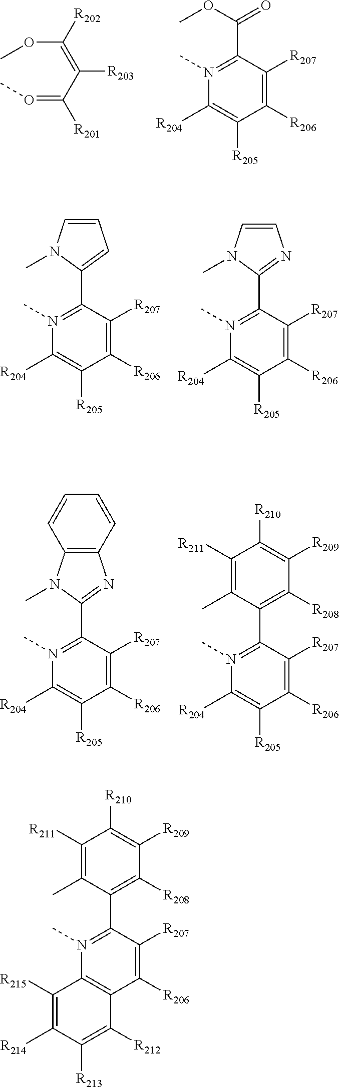

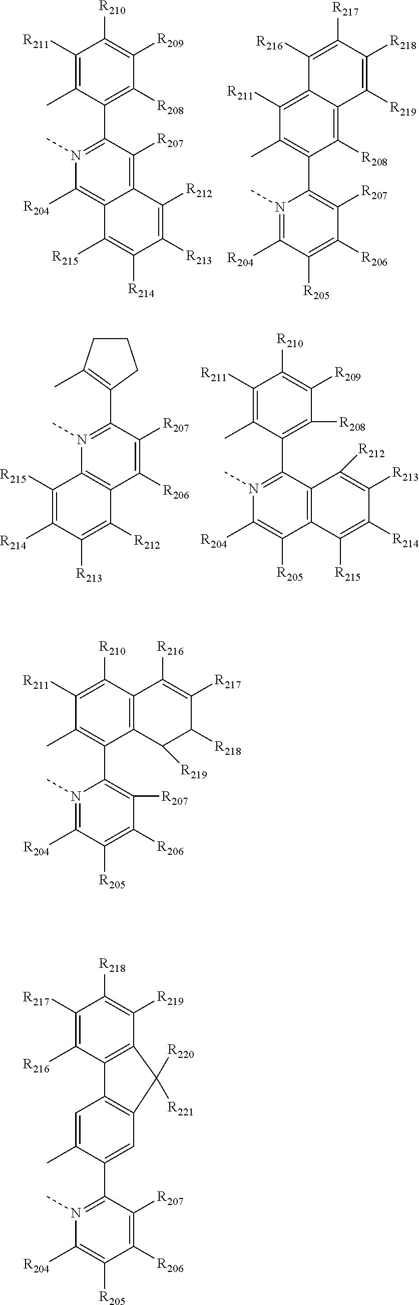

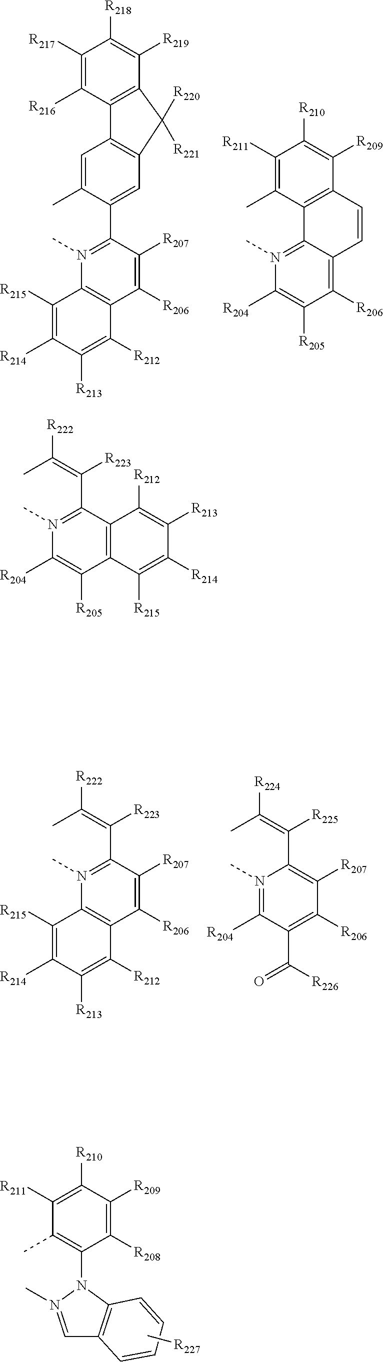

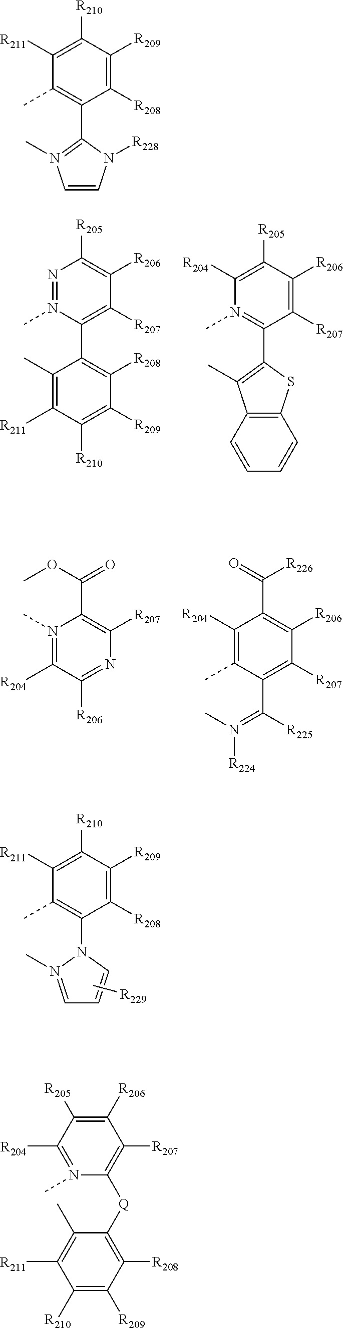

R₂₀₁ to R₂₀₃ each independently represent hydrogen, deuterium, a (C1-C30)alkyl group unsubstituted or substituted with halogen(s), a (C6-C30)aryl group unsubstituted or substituted with (C1-C30)alkyl group(s), or a halogen;

R₂₀₄ to R₂₁₉ each independently represent hydrogen, deuterium, a substituted or unsubstituted (C1-C30)alkyl group, a substituted or unsubstituted (C1-C30)alkoxy group, a substituted or unsubstituted (C3-C30)cycloalkyl group, a substituted or unsubstituted (C2-C30)alkenyl group, a substituted or unsubstituted (C6-C30)aryl group, a substituted or unsubstituted mono- or di-(C1-C30)alkylamino group, a substituted or unsubstituted mono- or di-(C6-C30)arylamino group, SF, a substituted or unsubstituted tri(C1-C30)alkylsilyl group, a substituted or unsubstituted di(C1-C30)alkyl(C6-C30)arylsilyl group, a substituted or unsubstituted tri(C6-C30)arylsilyl group, a cyano group or a halogen;

R₂₂₀ to R₂₂₃ each independently represent hydrogen, deuterium, a (C1-C30)alkyl group unsubstituted or substituted with halogen(s), or a (C6-C30)aryl group unsubstituted or substituted with (C1-C30)alkyl group(s);

R₂₂₄ and R₂₂₅ each independently represent hydrogen, deuterium, a substituted or unsubstituted (C1-C30)alkyl group, a substituted or unsubstituted (C6-C30)aryl group, or a halogen, or R₂₂₄ and R₂₂₅ may be linked to an adjacent substituent(s) to form a mono- or polycyclic, (C5-C30) alicyclic or aromatic ring;

R₂₂₆ represents a substituted or unsubstituted (C1-C30)alkyl group, a substituted or unsubstituted (C6-C30)aryl group, a substituted or unsubstituted 5- or 30-membered heteroaryl group or a halogen;

R₂₂₇ to R₂₂₉ each independently represent hydrogen, deuterium, a substituted or unsubstituted (C1-C30)alkyl group, a substituted or unsubstituted (C6-C30)aryl group or a halogen;

Q represents

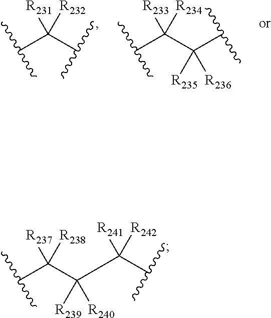

R₂₃₁ to R₂₄₂ each independently represent hydrogen, deuterium, a (C1-C30)alkyl group unsubstituted or substituted with halogen(s), a (C1-C30)alkoxy group, a halogen, a substituted or unsubstituted (C6-C30)aryl group, a cyano group, or a substituted or unsubstituted (C5-C30)cycloalkyl group, or each of R₂₃₁ to R₂₄₂ may be linked to an adjacent substituent via alkylene group or alkenylene group to form a spiro ring or a fused ring or may be linked to R₂₀₇ or R₂₀₈ via an alkylene group or an alkenylene group to form a saturated or unsaturated fused ring.

In detail, the compounds of the following formulas are preferably used as the dopant compound of formula 2:

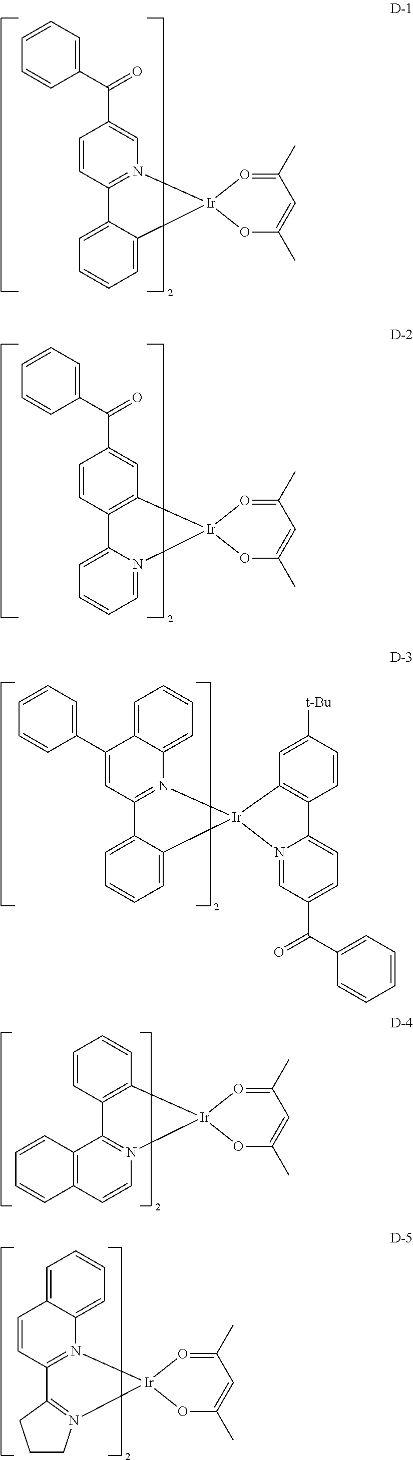

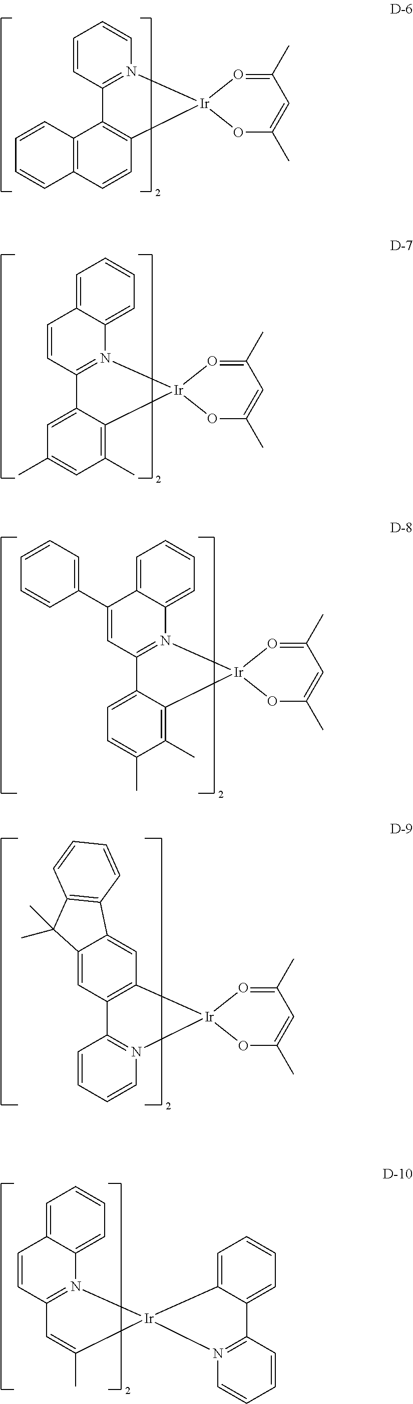

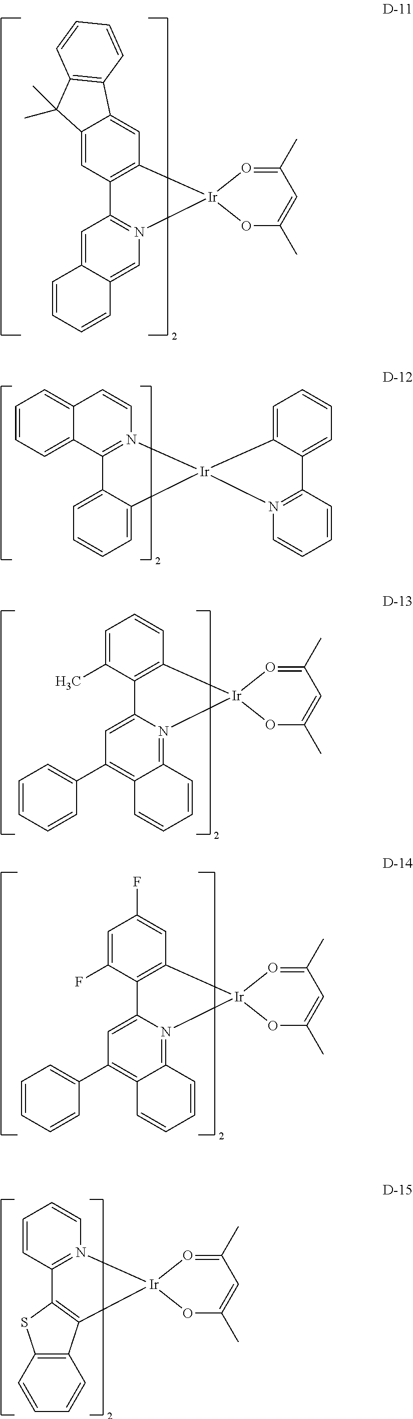

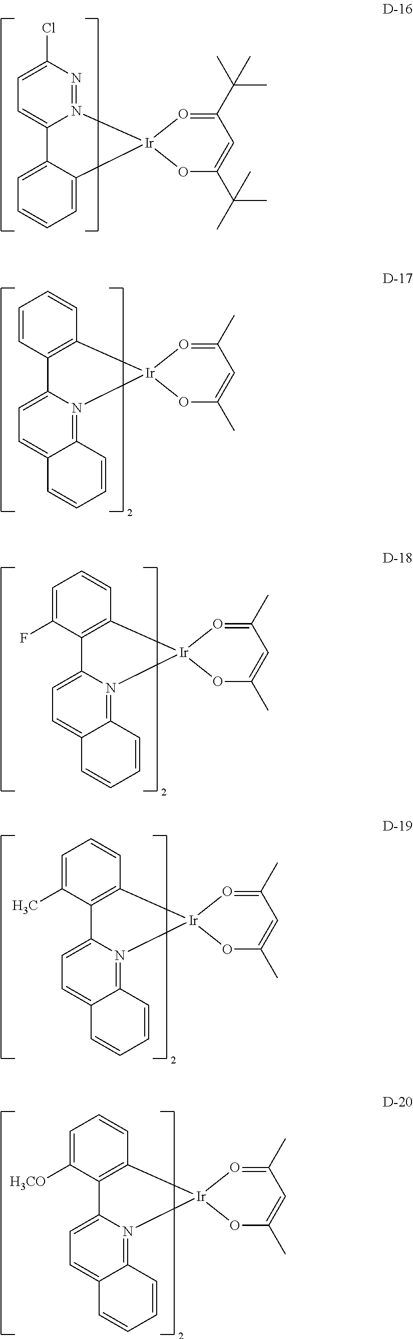

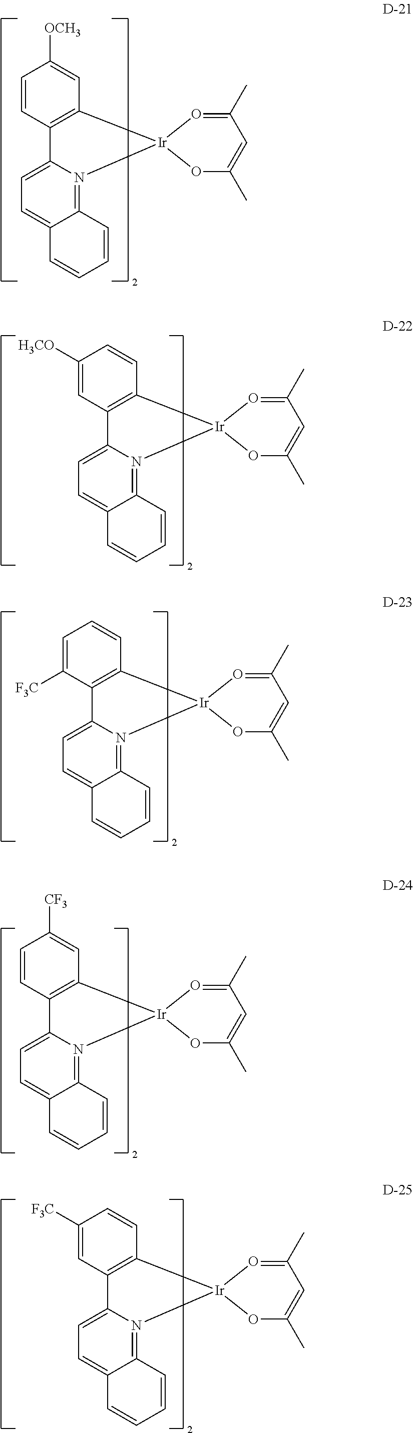

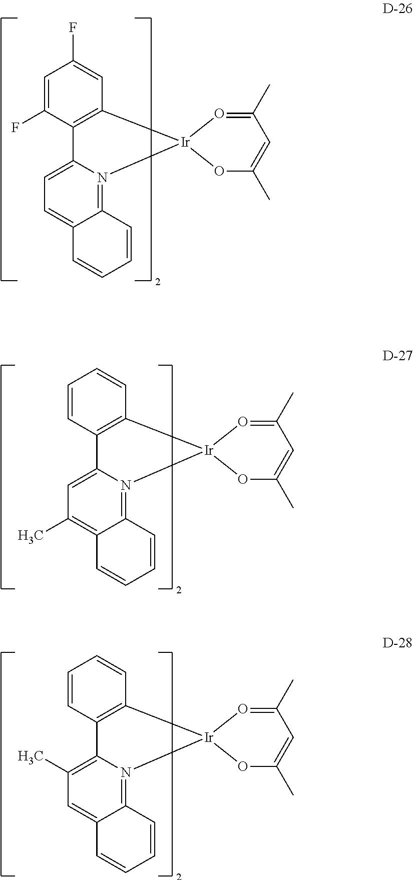

The organic electroluminescent device according to the present invention may further comprise, in addition to the compounds represented by formula 1, at least one compound selected from the group consisting of arylamine-based compounds and styrylarylamine-based compounds.

In the organic electroluminescent device according to the present invention, the organic layer may further comprise at least one metal selected from the group consisting of metals of Group 1, metals of Group 2, transition metals of the 4^{th} period, transition metals of the 5^{th} period, lanthanides and organic metals of d-transition elements of the Periodic Table, or at least one complex compound comprising the metal. The organic layer may comprise a light-emitting layer and a charge generating layer.

In addition, the organic electroluminescent device may emit white light by further comprising at least one light-emitting layer which comprises a blue electroluminescent compound, a red electroluminescent compound or a green electroluminescent compound, besides the compound according to the present invention.

Preferably, in the organic electroluminescent device according to the present invention, at least one layer (hereinafter, “a surface layer”) selected from a chalcogenide layer, a metal halide layer and a metal oxide layer may be placed on an inner surface(s) of one or both electrode(s). Specifically, it is preferred that a chalcogenide (includes oxides) layer of silicon or aluminum is placed on an anode surface of an electroluminescent medium layer, and a metal halide layer or metal oxide layer is placed on a cathode surface of an electroluminescent medium layer. Such a surface layer provides operation stability for the organic electroluminescent device. Preferably, the chalcogenide includes SiOₓ(1≦X≦2), AlOₓ(1≦X≦1.5), SiON, SiAlON, etc.; the metal halide includes LiF, MgF₂, CaF₂, a rare earth metal fluoride, etc.; and the metal oxide includes Cs₂O, Li₂O, MgO, SrO, BaO, CaO, etc.

Preferably, in the organic electroluminescent device according to the present invention, a mixed region of an electron transport compound and an reductive dopant, or a mixed region of a hole transport compound and an oxidative dopant may be placed on at least one surface of a pair of electrodes. In this case, the electron transport compound is reduced to an anion, and thus it becomes easier to inject and transport electrons from the mixed region to an electroluminescent medium. Further, the hole transport compound is oxidized to a cation, and thus it becomes easier to inject and transport holes from the mixed region to the electroluminescent medium. Preferably, the oxidative dopant includes various Lewis acids and acceptor compounds; and the reductive dopant includes alkali metals, alkali metal compounds, alkaline earth metals, rare-earth metals, and mixtures thereof. A reductive dopant layer may be employed as a charge generating layer to prepare an electroluminescent device having two or more electroluminescent layers and emitting a white light.

Hereinafter, the compound, the preparation method of the compound, and the luminescent properties of the device comprising the compound of the present invention will be explained in detail with reference to the following examples:

### PREPARATION EXAMPLE 1

### Preparation of Compound C-2

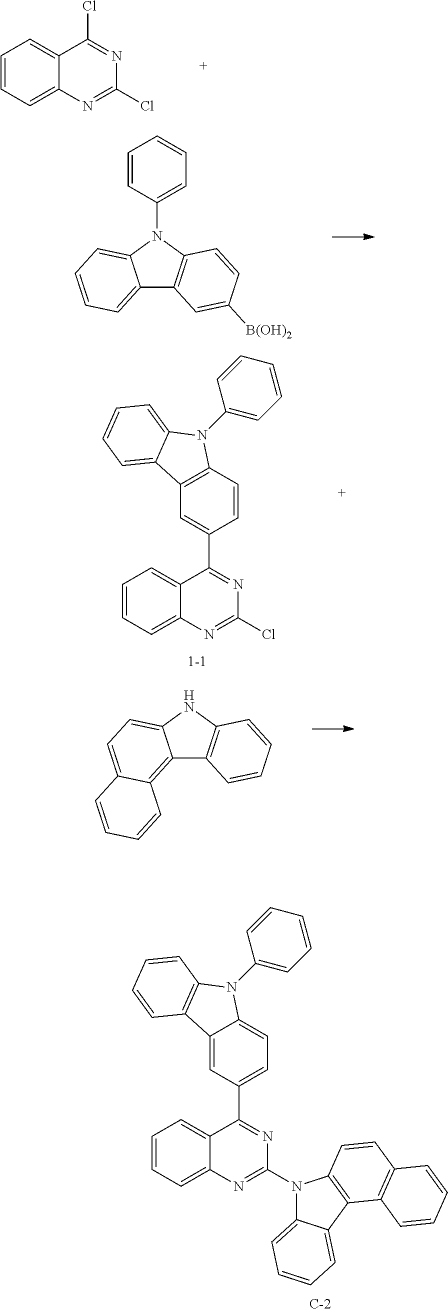

Preparation of Compound 1-1

After dissolving 2,4-dichloroquinazoline (30 g, 151 mmol), 9-phenyl-9H-carbazol-3-yl boronic acid (15.6 g, 75.3 mmol), Pd(PPh₃)₄(2.6 g, 2.3 mmol) and Na₂CO₃(16 g, 150 mmol) in a mixture of toluene (300 mL) and distilled water (75 mL), the reaction mixture was stirred for 2 hours at 90° C. After terminating the reaction, the reaction mixture was cooled to room temperature, the resulting organic layer was distillated under reduced pressure, and then was triturated with MeOH. The obtained solid was dissolved in methylene chloride (MC), was filtered through silica, and then was triturated with MC and n-hexane to produce compound 1-1 (9.3 g, 51.4%).

Preparation of Compound C-2

After suspending 7H-benzo[c]carbazole (3.2 g, 14.7 mmol) and compound 1-1 (5 g, 15.8 mmol) in dimethyl formamide (DMF) (80 mL), 60% NaH (948 mg, 22 mmol) was added to the mixture at room temperature, and was stirred for 12 hours. After adding purified water (1 L), the mixture was filtered under reduced pressure. The obtained solid was triturated with MeOH/ethylacetate(EA), was dissolved in MC, was filtered through silica, and then was triturated with MC and n-hexane to produce compound C-2 (5 g, 51.5%).

MS/FAB found 589; calculated 586.68

### PREPARATION EXAMPLE 2

### Preparation of Compound C-57

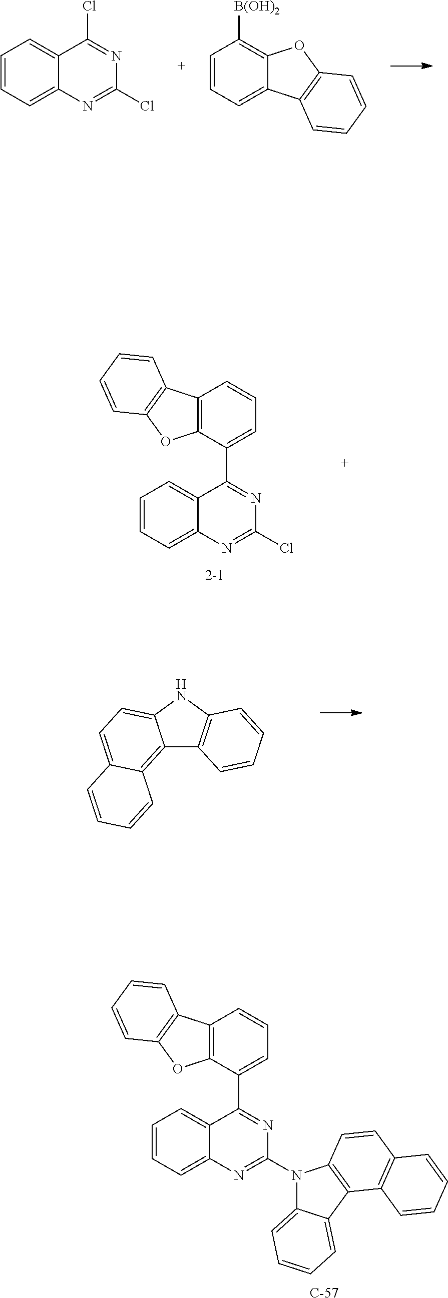

Preparation of Compound 2-1

After dissolving 2,4-dichloroquinazoline (50 g, 251 mmol) and dibenzo[b,a]furan-4-yl boronic acid (53.2 g, 251 mmol) in a mixture of toluene (1 L) and water (200 mL), Pd(PPh₃)₄ (14.5 g, 12.5 mmol) and Na₂CO₃ (80 g, 755 mmol) were added to the reaction mixture, and was stirred for 20 hours at 80° C. The reaction mixture was cooled to room temperature. After terminating the reaction with ammonium chloride aqueous solution 200 mL, the reaction mixture was extracted with ethyl acetate 1 L, and further an aqueous layer was extracted with dichloromethane 1 L. The obtained organic layer was dried with anhydrous magnesium sulfate to remove the residual moisture, and the organic solvent was removed under reduced pressure. The obtained solid was filtered through silica gel, and the solvent was removed under reduced pressure. The obtained solid was washed with ethyl acetate (100 mL) to produce compound 2-1 (50 g, 74%).

Preparation of Compound C-57

After dissolving H-benzo[c]carbazole (26 g, 122 mmol) in DMF, 60% NaH (5.9 g, 148 mmol) was added slowly to the reaction mixture, and was stirred for 1 hour at room temperature. Compound 2-1 (51 g, 147 mmol) was added to the reaction mixture, and was stirred for 20 hours at room temperature. Iced water was dropped slowly to the reaction mixture to terminate the reaction, and was filtered to obtain the produced solid. The obtained solid was washed with water (1 L), and subsequently with MeOH (1 L). The obtained solid was dried, dissolved in CHCl₃ (4 L), and filtered through silica gel to remove an inorganic material. The solvent in the obtained solution was removed to obtain solid. The obtained solid was recrystallized in DMF to obtain compound C-57 (50 g, 58%).

MS/FAB found 512; calculated 511.57

### PREPARATION EXAMPLE 3

### Preparation of Compound C-58

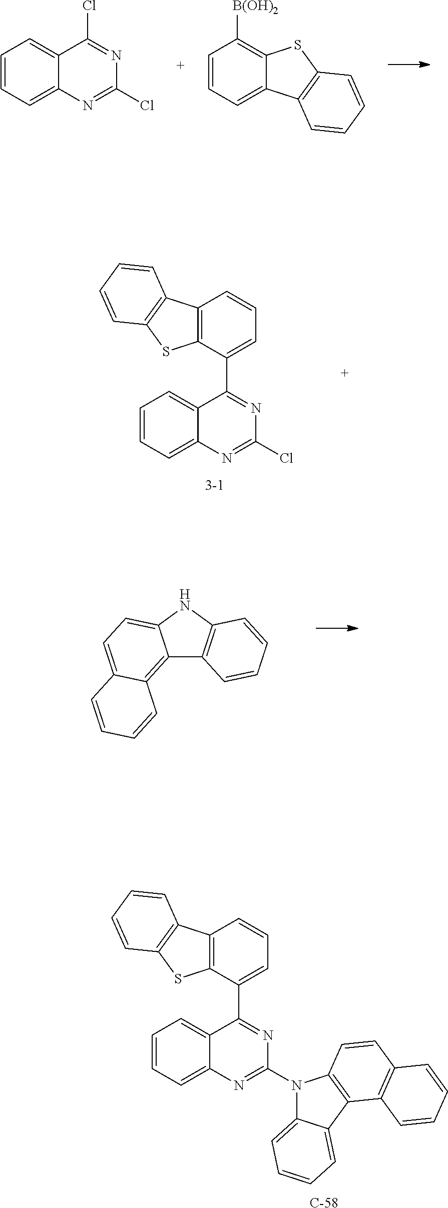

Preparation of Compound 3-1

After dissolving 2,4-dichloroquinazoline (50 g, 251 mmol) and dibenzo[b,a]furan-4-yl boronic acid (57.3 g, 251 mmol) in a mixture of toluene (1 L) and water (200 mL), Pd(PPh₃)₄ (14.5 g, 12.5 mmol) and Na₂CO₃ (80 g, 755 mmol) were added to the reaction mixture, and was stirred for 20 hours at 80° C. The reaction mixture was cooled to room temperature. After terminating the reaction with ammonium chloride aqueous solution 200 mL, the reaction mixture was extracted with ethyl acetate 1 L, and further an aqueous layer was extracted with dichloromethane 1 L. The obtained organic layer was dried with anhydrous magnesium sulfate to remove the residual moisture, and the organic solvent was removed under reduced pressure. The obtained solid was filtered through silica gel, and the solvent was removed under reduced pressure. The obtained solid was washed with ethyl acetate (100 mL) to produce compound 3-1 (50 g, 60%).

Preparation of Compound C-58

After dissolving 7H-benzo[c]carbazole (26 g, 122 mmol) in DMF, 60% NaH (5.9 g, 148 mmol) was added slowly to the reaction mixture, and was stirred for 1 hour at room temperature. Compound 3-1 (51 g, 147 mmol) was added to the reaction mixture, and was stirred for 20 hours at room temperature. Iced water was dropped slowly to the reaction mixture to terminate the reaction, and was filtered to obtain the produced solid. The obtained solid was washed with water (1 L), and subsequently with MeOH (1 L). The obtained solid was dried, dissolved in CHCl₃ (4 L), and filtered through silica gel to remove an inorganic material. The solvent in the obtained solution was removed to obtain solid. The obtained solid was recrystallized in DMF to obtain compound C-58 (50 g, 57%).

MS/FAB found 528; calculated 527.64

### PREPARATION EXAMPLE 4

### Preparation of compound C-75

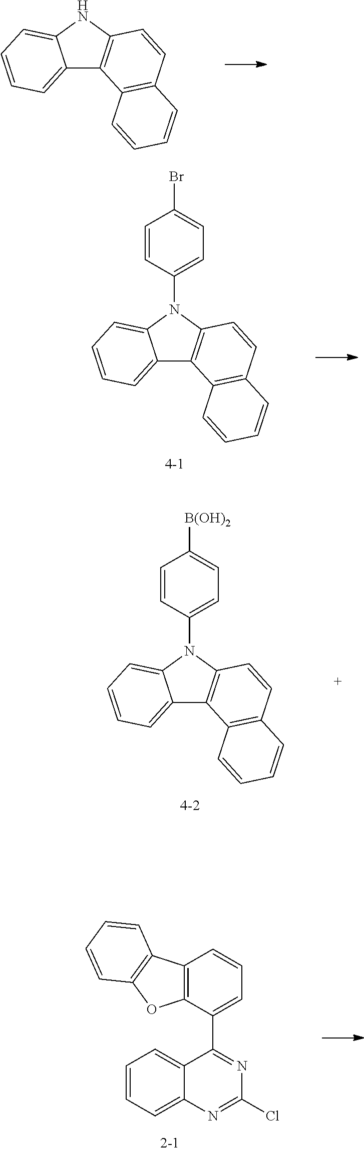

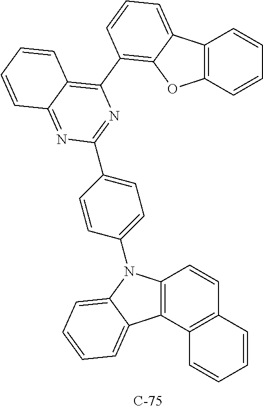

Preparation of Compound 4-1

After putting 7H-benzo[c]carbazole (7.3 g, 34.3 mmol), 1-bromo-4-iodobenzene (48.5 g, 171.4 mmol), CuI (3.3 g, 17.1 mmol), K₃PO₄ (21.8 g, 102.9 mmol) and ethylenediamine (EDA, 2.3 mL, 34.3 mmol) in toluene (500 mL), the reaction mixture was stirred under reflux for 24 hours. The reaction mixture was extracted with ethylacetate, was distillated under reduced pressure, and then was filtered through column with MC and hexane to obtain compound 4-1 (15.5 g, 80.1%).

Preparation of Compound C-4-2

After dissolving compound 4-1 (10.2 g, 27.5 mmol) in tetrahydrofurane (THF) (250 mL), and adding 2.5 M n-BuLi in hexane (17.6 mL, 44 mmol) to the reaction mixture in −78° C., the reaction mixture was stirred for 1 hour. The reaction mixture was stirred for 2 hours with adding B(Oi-Pr)₃ (12.6 mL, 55 mmol) slowly to the reaction mixture. After quenching the reaction mixture with adding 2 M HCl, the reaction mixture was extracted with distilled water and ethylacetate. The resulting organic layer was distillated under reduced pressure, and then was recrystallized with MC and hexane to obtain compound 4-2 (8.7 g, 60%).

Preparation of Compound C-75

After dissolving compound 2-1 (3.2 g, 9.2 mmol), compound 4-2 (3.1 g, 9.2 mmol), Pd(PPh₃)₄ (532 mg, 0.46 mmol) and Na₂CO₃ (2.9 g, 27.6 mmol) in a mixture of toluene (55 mL), EtOH (14 mL) and distilled water (14 mL), the reaction mixture was stirred for 2 hours at 90° C. The reaction mixture was extracted with distilled water and EA, and was filtered through column with MC and hexane to obtain compound C-75 (5.5 g, 75%).

MS/FAB found 588; calculated 587.67

### EXAMPLE 1

### Production of an OLED Device Using the Compound According to the Present Invention

OLED device was produced using the compound according to the present invention. A transparent electrode indium tin oxide (ITO) thin film (15 Ω/sq) on a glass substrate for an organic light-emitting diode (OLED) device (Samsung Corning, Republic of Korea) was subjected to an ultrasonic washing with trichloroethylene, acetone, ethanol and distilled water, sequentially, and then was stored in isopropanol. Then, the ITO substrate was mounted on a substrate holder of a vacuum vapor depositing apparatus. N1,N1′-([1,1′-biphenyl]-4,4′-diyl)bis(N1-(naphthalen-1-yl)-N4,N4-diphenylbenzene-1,4,-diamine) was introduced into a cell of the vacuum vapor depositing apparatus, and then the pressure in the chamber of the apparatus was controlled to 10′ torr. Thereafter, an electric current was applied to the cell to evaporate the above introduced material, thereby forming a hole injection layer having a thickness of 60 nm on the ITO substrate. Then, N,N′-di(4-biphenyl)-N,N′-di(4-biphenyl)-4,4′-diaminobiphenyl was introduced into another cell of the vacuum vapor depositing apparatus, and was evaporated by applying electric current to the cell, thereby forming a hole transport layer having a thickness of 20 nm on the hole injection layer. Thereafter, compound C-2 was introduced into one cell of the vacuum vapor depositing apparatus, as a host material, and compound D-7 was introduced into another cell as a dopant. The two materials were evaporated at different rates and were deposited in a doping amount of 4 wt % to form a light-emitting layer having a thickness of 30 nm on the hole transport layer. Then, 2-(4-(9,10-di(naphthalene-2-yl)anthracen-2-yl)phenyl)-1-phenyl-1H-benzo[d]imidazole was introduced into one cell and lithium quinolate was introduced into another cell. The two materials were evaporated at same rates and were deposited in a doping amount of 50 wt % to form an electron transport layer having a thickness of 30 nm on the light-emitting layer. Then, after depositing lithium quinolate as an electron injection layer having a thickness of 2 nm on the electron transport layer, an Al cathode having a thickness of 150 nm was deposited by another vacuum vapor deposition apparatus on the electron injection layer. Thus, an OLED device was produced. All the material used for producing the OLED device were those purified by vacuum sublimation at 10⁻⁶ torr.

The produced OLED device showed red emission having a luminance of 1,030 cd/m² and a current density of 7.8 mA/cm² at a driving voltage of 3.9 V. Further, the minimum time taken to be reduced to 90% of the luminance at a luminance of 5,000 nit was 80 hours.

### EXAMPLE 2

### Production of an OLED Device Using the Compound According to the Present Invention

An OLED device was produced in the same manner as in Example 1, except for using compound C-21 as a host material, and compound D-11 as a dopant.

The produced OLED device showed red emission having a luminance of 1,020 cd/m² and a current density of 13.2 mA/cm² at a driving voltage of 4.2 V. Further, the minimum time taken to be reduced to 90% of the luminance at a luminance of 5,000 nit was 50 hours.

### EXAMPLE 3

### Production of an OLED Device Using the Compound According to the Present Invention

An OLED device was produced in the same manner as in Example 1, except for using compound C-57 as a host material, and compound D-7 as a dopant.

The produced OLED device showed red emission having a luminance of 1,060 cd/m² and a current density of 7.8 mA/cm² at a driving voltage of 3.9 V. Further, the minimum time taken to be reduced to 90% of the luminance at a luminance of 5,000 nit was 100 hours.

### EXAMPLE 4

### Production of an OLED Device Using the Compound According to the Present Invention

An OLED device was produced in the same manner as in Example 1, except for using compound C-75 as a host material, and compound D-11 as a dopant.

The produced OLED device showed red emission having a luminance of 1,050 cd/m² and a current density of 13.1 mA/cm² at a driving voltage of 4.2 V. Further, the minimum time taken to be reduced to 90% of the luminance at a luminance of 5,000 nit was 40 hours.

### COMPARATIVE EXAMPLE 1

### Production of an OLED Device Using Conventional Electroluminescent Compounds

An OLED device was produced in the same manner as that of Example 1, except that a light-emitting layer having a thickness of 30 nm was deposited on the hole transport layer by using 4,4′-N,N′-dicarbazol-biphenyl as a host material and compound D-11 as a dopant and that a hole blocking layer having a thickness of 10 nm was deposited by using aluminum(III) bis(2-methyl-8-guinolinato)-4-phenylphenolate.

The produced OLED device showed red emission having a luminance of 1,000 cd/m² and a current density of 20.0 mA/cm² at a driving voltage of 8.2V. Further, the minimum time taken to be reduced to 90% of the luminance at a luminance of 5,000 nit was 10 hours.

The compounds of the present invention have superior luminous efficiency and longer lifetime than the conventional materials. The device containing the compounds according to the present invention as a host material induces an increase in power efficiency by reducing a driving voltage, and thus can improve power consumption, and have a long operation lifetime.

1. A compound represented by the following formula 1: 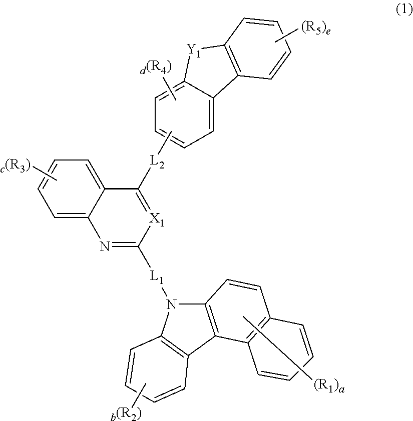
wherein
L₁ and L₂ each independently represent a single bond, a substituted or unsubstituted 3- to 30-membered heteroarylene group, a substituted or unsubstituted (C6-C30)arylene group, or a substituted or unsubstituted (C6-C30)cycloalkylene group;
X₁ represents CH or N;
Y₁ represents —O—, —S—, —CR₆R₇— or —NR₈—;
R₁ to R₅ each independently represent hydrogen, deuterium, a halogen, a substituted or unsubstituted (C1-C30)alkyl group, a substituted or unsubstituted (C6-C30)aryl group, a substituted or unsubstituted 3- to 30-membered heteroaryl group, a substituted or unsubstituted (C3-C30)cycloalkyl group, a substituted or unsubstituted 5- to 7-membered heterocycloalkyl group, a substituted or unsubstituted (C6-C30)aryl(C1-C30)alkyl group, —NR₁₁R₁₂, —SiR₁₃R₁₄R₁₅, —SR₁₆, —OR₁₇, a cyano group, a nitro group, or a hydroxyl group; or R₄ and R₅ each independently are linked to an adjacent substituent(s) to form a mono- or polycyclic, (C5-C30) alicyclic or aromatic ring whose carbon atom(s) may be replaced with at least one hetero atom selected from nitrogen, oxygen and sulfur;
R₆ to R₈ and R₁₁ to R₁₇ each independently represent hydrogen, deuterium, a halogen, a substituted or unsubstituted (C1-C30)alkyl group, a substituted or unsubstituted (C6-C30)aryl group, a substituted or unsubstituted 3- to 30-membered heteroaryl group, a substituted or unsubstituted 5- to 7-membered heterocycloalkyl group, or a substituted or unsubstituted (C3-C30)cycloalkyl group; or are linked to an adjacent substituent(s) to form a mono- or polycyclic, (C5-C30) alicyclic or aromatic ring whose carbon atom(s) may be replaced with at least one hetero atom selected from nitrogen, oxygen and sulfur;
a represents an integer of 1 to 6; where a is an integer of 2 or more, each of R₁ is the same or different;
b, c and e each independently represent an integer of 1 to 4; where b, c or e is an integer of 2 or more, each of R₂, each of R₃ or each of R₅ is the same or different;
d represents an integer of 1 to 3; where d is an integer of 2 or more, each of R₄ is the same or different; and
the heterocycloalkyl group and the heteroaryl(ene) group contain at least one hetero atom selected from B, N, O, S, P(═O), Si and P.

2. The compound according to claim 1, wherein substituents of the substituted alkyl(ene) group, the substituted aryl(ene) group, the substituted heteroaryl(ene) group, the substituted cycloalkyl(ene) group, the substituted heterocycloalkyl group, the substituted aralkyl group and the substituted alkenylene in L₁, L₂, R₁ to R₅, R₆ to R₈ and R₁₁ to R₁₇ groups each independently are at least one selected from the group consisting of deuterium, a halogen, a (C1-C30)alkyl group substituted or unsubstituted with a halogen, a (C6-C30)aryl group, a 3- to 30-membered heteroaryl group substituted or unsubstituted with a (C6-C30)aryl, a (C3-C30)cycloalkyl group, a 3- to 7-membered heterocycloalkyl group, a tri(C1-C30)alkylsilyl group, a tri(C6-C30)arylsilyl group, a di(C1-C30)alkyl (C6-C30)arylsilyl group, a (C1-C30)alkyl di(C6-C30)arylsilyl group, a (C2-C30)alkenyl group, a (C2-C30)alkynyl group, a cyano group, a carbazolyl group, a di(C1-C30)alkylamino group, a di(C6-C30)arylamino group, a (C1-C30)alkyl (C6-C30)arylamino group, a di(C6-C30)arylboronyl group, a di(C1-C30)alkylboronyl group, a (C1-C30)alkyl (C6-C30)arylboronyl group, a (C6-C30)aryl (C1-C30)alkyl group, a (C1-C30)alkyl (C6-C30)aryl group, a carboxyl group, a nitro group and a hydroxyl group.

3. The compound according to claim 1, wherein
L₁ and L₂ each independently represent a single bond, a 3- to 30-membered heteroarylene group, a (C6-C30)arylene group, or a (C6-C30)cycloalkylene group;
X₁ represents CH or N;
Y₁ represents —O—, —S—, —CR₆R₇— or —NR₈—;
R₁ to R₅ each independently represent hydrogen, deuterium, a halogen, a (C1-C30)alkyl group, a (C6-C30)aryl group, a 3- to 30-membered heteroaryl group, a N-carbazolyl group, —NR₁₁R₁₂, or —SiR₁₃R₁₄R₁₅; or R₄ and R₅ each independently are linked to an adjacent substituent(s) to form a mono- or polycyclic, (C5-C30) alicyclic or aromatic ring whose carbon atom(s) may be replaced with at least one hetero atom selected from nitrogen, oxygen and sulfur;
R₆ to R₈ each independently represent hydrogen, deuterium, a halogen, a (C1-C30)alkyl group, a (C6-C30)aryl group, or a 3- to 30-membered heteroaryl group;
R₁₁ to R₁₅ each independently represent a (C1-C30)alkyl group, a (C6-C30)aryl group, or a 3- to 30-membered heteroaryl group; and
the arylene group, the heteroarylene group and the cycloalkylene group in L₁ and L₂, and the alkyl group, the aryl group and the heteroaryl group in R₁ to R₅ and R₁₁ to R₁₅ each independently can be substituted with at least one selected from the group consisting of deuterium, a halogen, a (C1-C30)alkyl group substituted or unsubstituted with a halogen, a (C6-C30)aryl group, a (C1-C30)alkyl (C6-C30)aryl group, a 3- to 30-membered heteroaryl group substituted or unsubstituted with a (C6-C30)aryl, a (C3-C30)cycloalkyl group, and a (C6-C30)aryl (C1-C30)alkyl group.

4. The compound according to claim 1, wherein
the moiety: 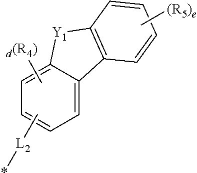
in formula 1 is selected from the following structures:

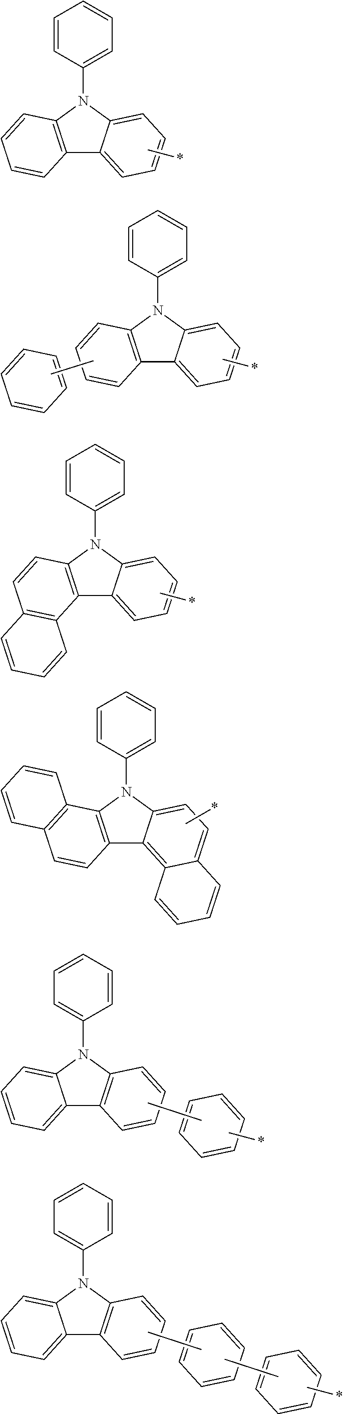

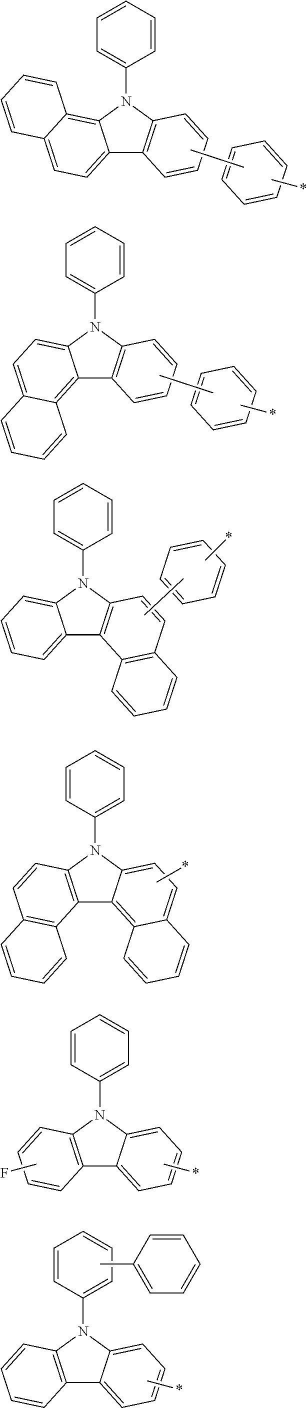

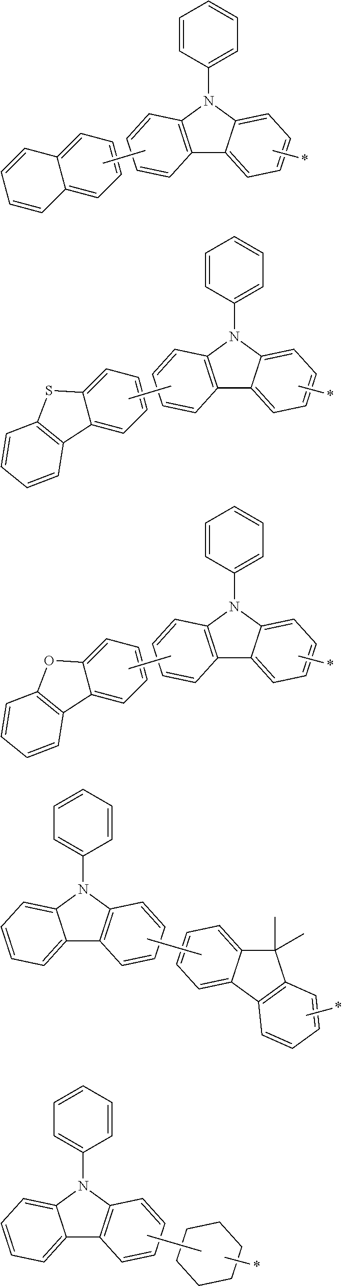

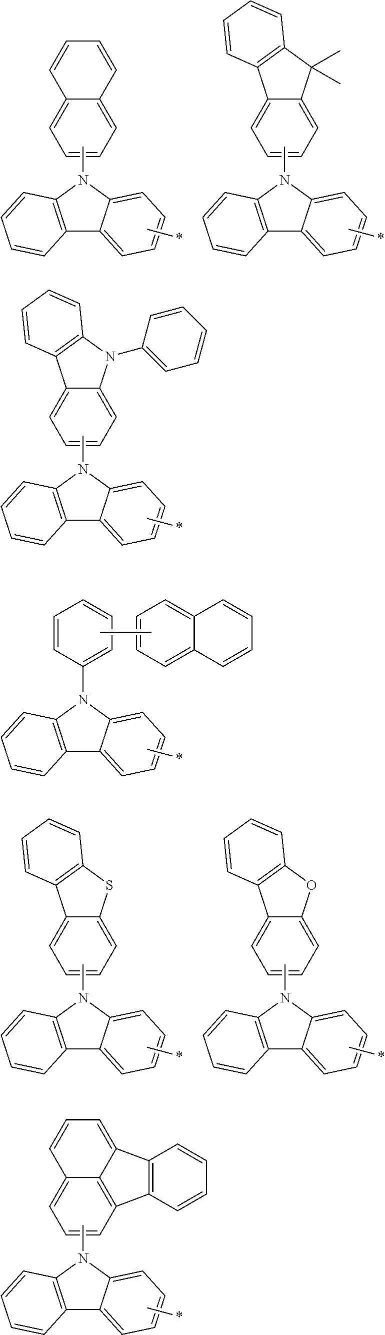

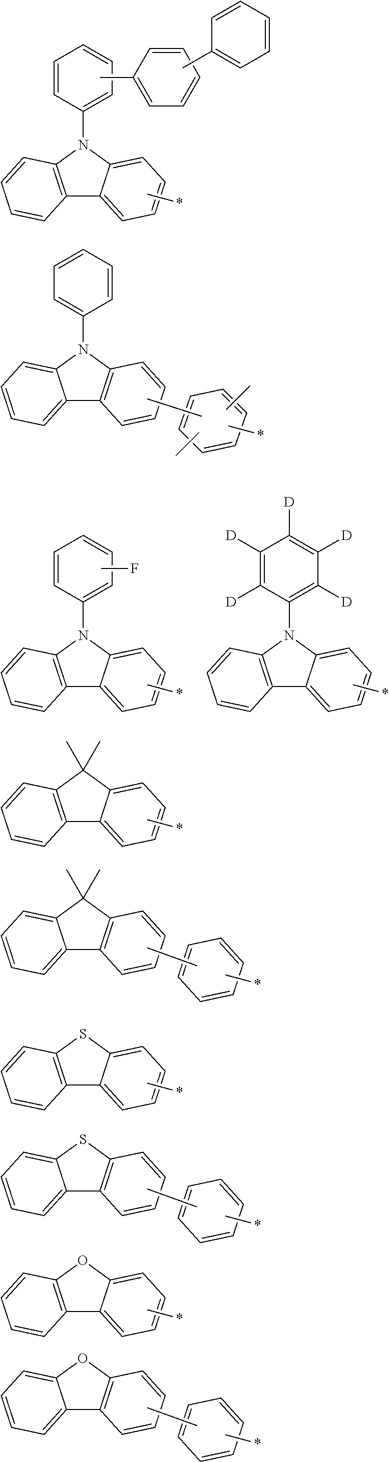

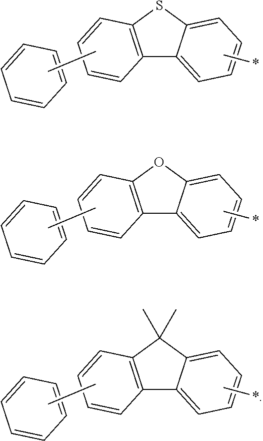

5. The compound according to claim 1, wherein the compound represented by formula 1 is selected from the group consisting of:

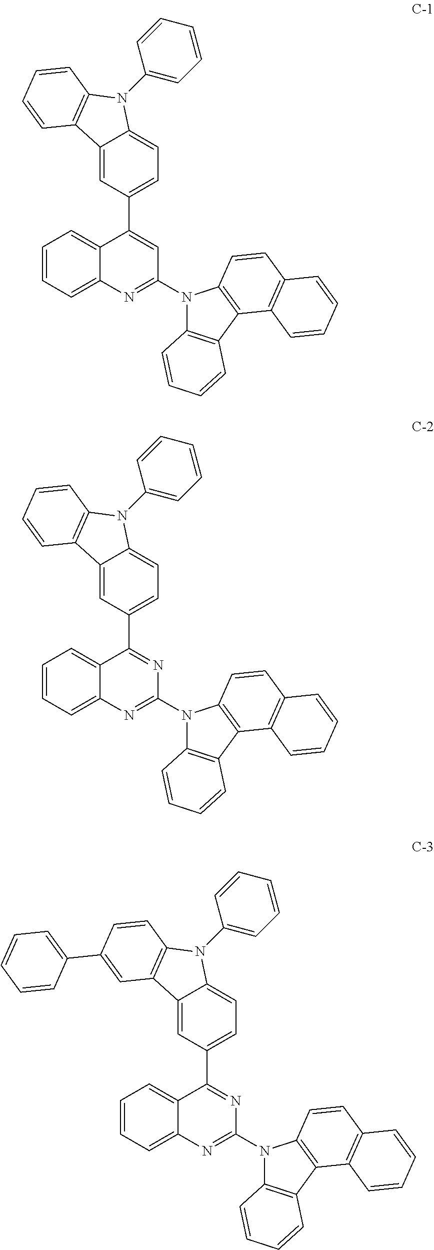 [SMILES: c1ccc(-n2c3ccccc3c3cc(-c4cc(-n5c6ccccc6c6c7ccccc7ccc65)nc5ccccc45)ccc32)cc1 ; c1ccc(-n2c3ccccc3c3cc(-c4nc(-n5c6ccccc6c6c7ccccc7ccc65)nc5ccccc45)ccc32)cc1 ; c1ccc(-c2ccc3c(c2)c2cc(-c4nc(-n5c6ccccc6c6c7ccccc7ccc65)nc5ccccc45)ccc2n3-c2ccccc2)cc1]

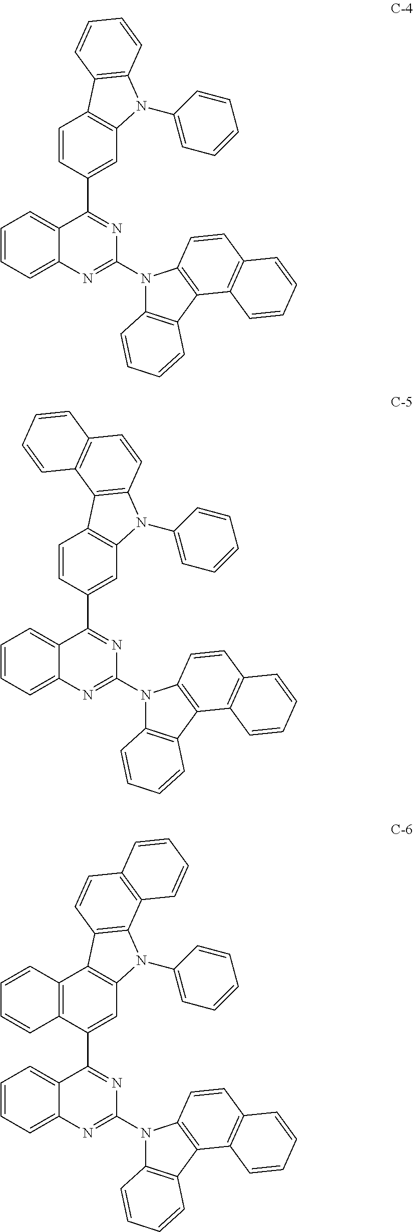

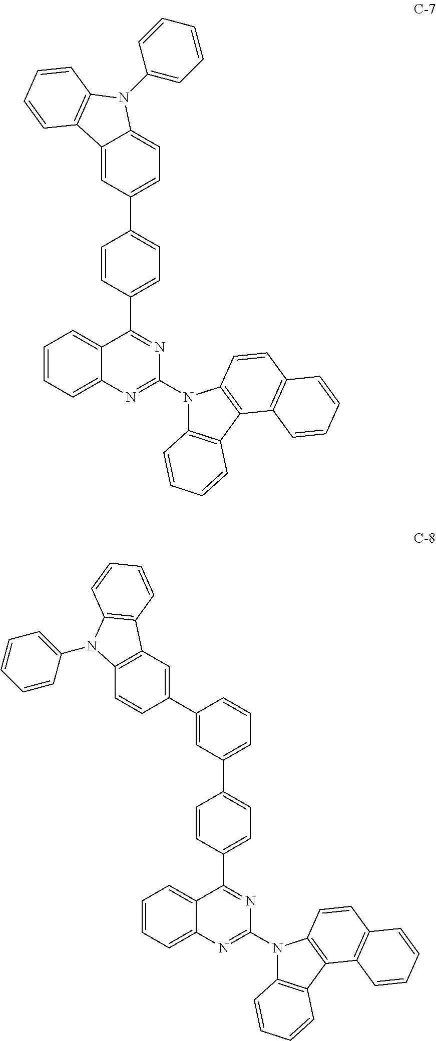 [SMILES: c1ccc(-n2c3ccccc3c3cc(-c4ccc(-c5nc(-n6c7ccccc7c7c8ccccc8ccc76)nc6ccccc56)cc4)ccc32)cc1 ; c1ccc(-n2c3ccccc3c3cc(-c4cccc(-c5ccc(-c6nc(-n7c8ccccc8c8c9ccccc9ccc87)nc7ccccc67)cc5)c4)ccc32)cc1]

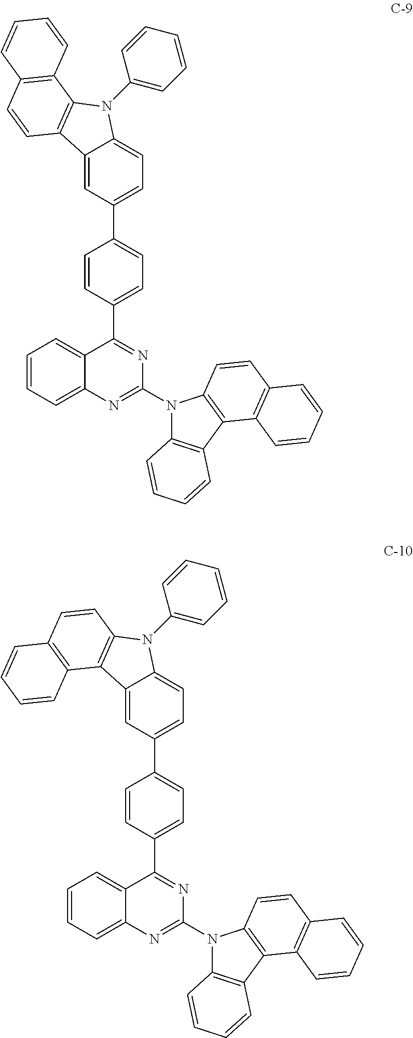 [SMILES: c1ccc(-n2c3ccc(-c4ccc(-c5nc(-n6c7ccccc7c7c8ccccc8ccc76)nc6ccccc56)cc4)cc3c3ccc4ccccc4c32)cc1 ; c1ccc(-n2c3ccc(-c4ccc(-c5nc(-n6c7ccccc7c7c8ccccc8ccc76)nc6ccccc56)cc4)cc3c3c4ccccc4ccc32)cc1]

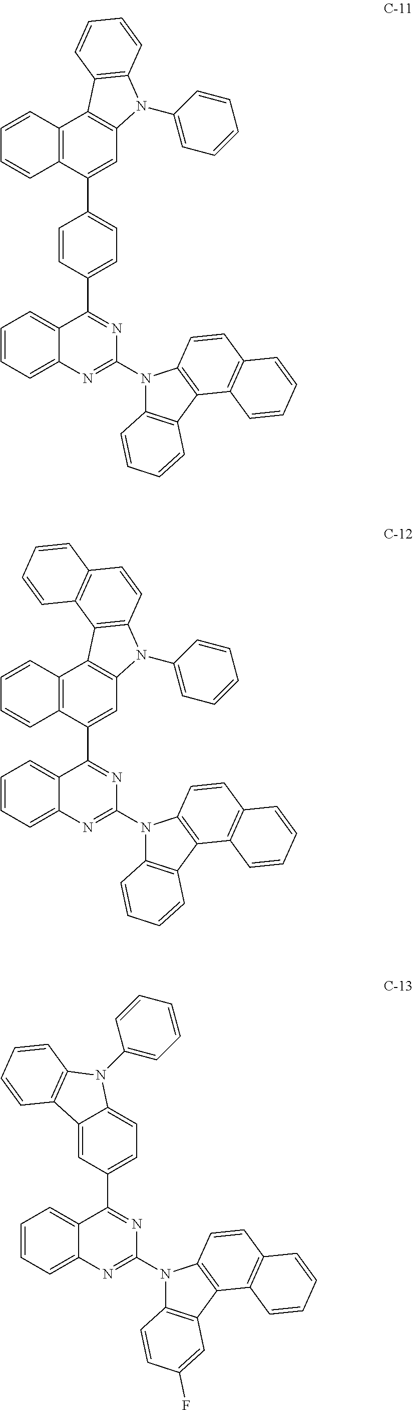 [SMILES: c1ccc(-n2c3ccccc3c3c4ccccc4c(-c4ccc(-c5nc(-n6c7ccccc7c7c8ccccc8ccc76)nc6ccccc56)cc4)cc32)cc1 ; c1ccc(-n2c3ccc4ccccc4c3c3c4ccccc4c(-c4nc(-n5c6ccccc6c6c7ccccc7ccc65)nc5ccccc45)cc32)cc1 ; Fc1ccc2c(c1)c1c3ccccc3ccc1n2-c1nc(-c2ccc3c(c2)c2ccccc2n3-c2ccccc2)c2ccccc2n1]

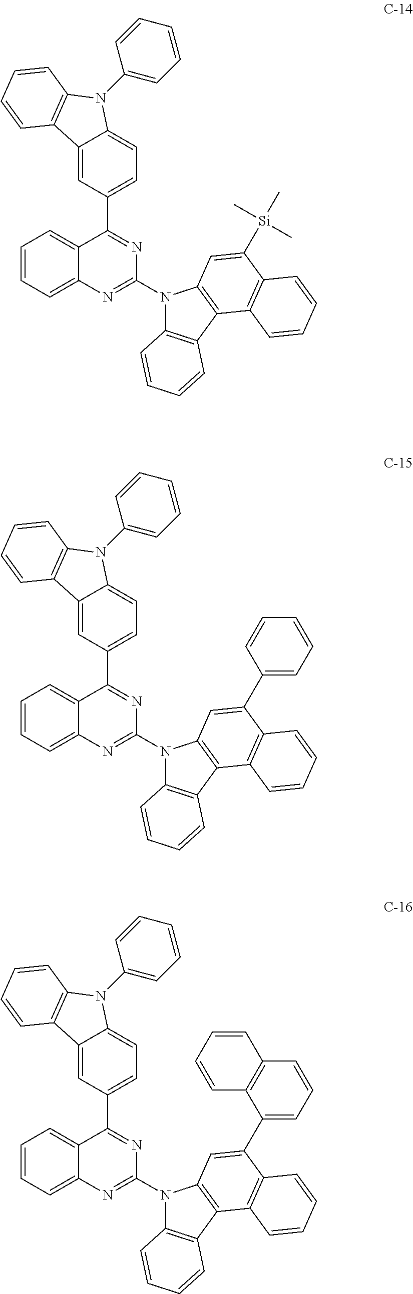 [SMILES: C[Si](C)(C)c1cc2c(c3ccccc13)c1ccccc1n2-c1nc(-c2ccc3c(c2)c2ccccc2n3-c2ccccc2)c2ccccc2n1 ; c1ccc(-c2cc3c(c4ccccc24)c2ccccc2n3-c2nc(-c3ccc4c(c3)c3ccccc3n4-c3ccccc3)c3ccccc3n2)cc1 ; c1ccc(-n2c3ccccc3c3cc(-c4nc(-n5c6ccccc6c6c7ccccc7c(-c7cccc8ccccc78)cc65)nc5ccccc45)ccc32)cc1]

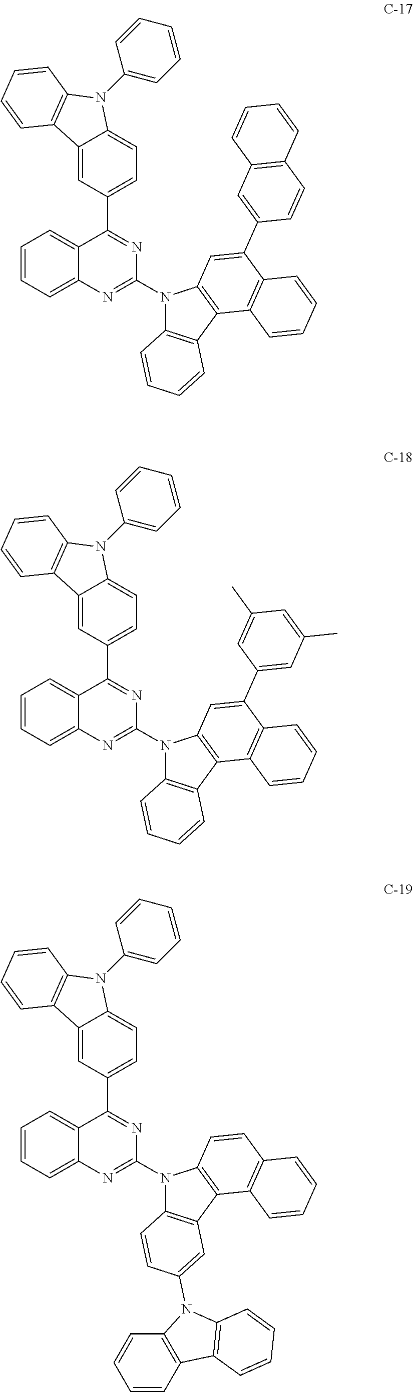 [SMILES: c1ccc(-n2c3ccccc3c3cc(-c4nc(-n5c6ccccc6c6c7ccccc7c(-c7ccc8ccccc8c7)cc65)nc5ccccc45)ccc32)cc1 ; Cc1cc(C)cc(-c2cc3c(c4ccccc24)c2ccccc2n3-c2nc(-c3ccc4c(c3)c3ccccc3n4-c3ccccc3)c3ccccc3n2)c1 ; c1ccc(-n2c3ccccc3c3cc(-c4nc(-n5c6ccc(-n7c8ccccc8c8ccccc87)cc6c6c7ccccc7ccc65)nc5ccccc45)ccc32)cc1]

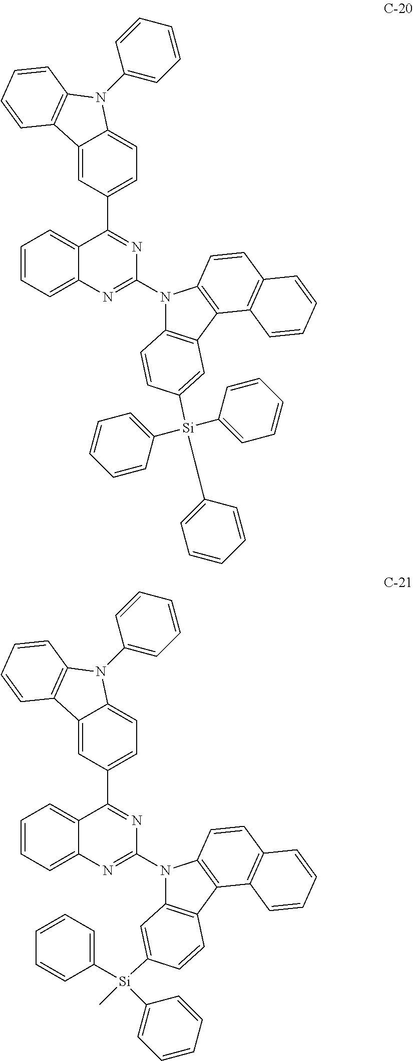 [SMILES: c1ccc(-n2c3ccccc3c3cc(-c4nc(-n5c6ccc([Si](c7ccccc7)(c7ccccc7)c7ccccc7)cc6c6c7ccccc7ccc65)nc5ccccc45)ccc32)cc1 ; C[Si](c1ccccc1)(c1ccccc1)c1ccc2c3c4ccccc4ccc3n(-c3nc(-c4ccc5c(c4)c4ccccc4n5-c4ccccc4)c4ccccc4n3)c2c1]

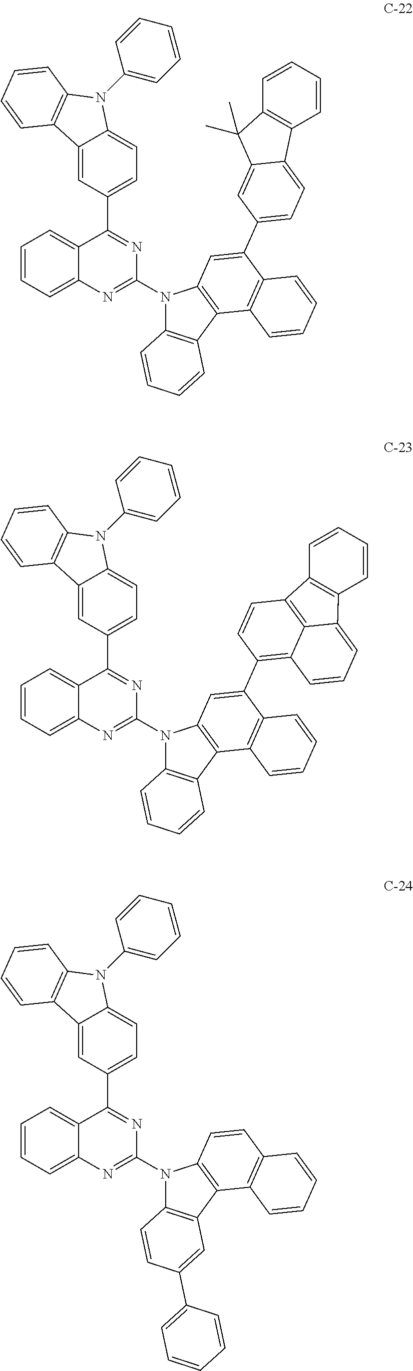 [SMILES: CC1(C)c2ccccc2-c2ccc(-c3cc4c(c5ccccc35)c3ccccc3n4-c3nc(-c4ccc5c(c4)c4ccccc4n5-c4ccccc4)c4ccccc4n3)cc21 ; c1ccc(-n2c3ccccc3c3cc(-c4nc(-n5c6ccccc6c6c7ccccc7c(-c7ccc8c9c(cccc79)-c7ccccc7-8)cc65)nc5ccccc45)ccc32)cc1 ; c1ccc(-c2ccc3c(c2)c2c4ccccc4ccc2n3-c2nc(-c3ccc4c(c3)c3ccccc3n4-c3ccccc3)c3ccccc3n2)cc1]

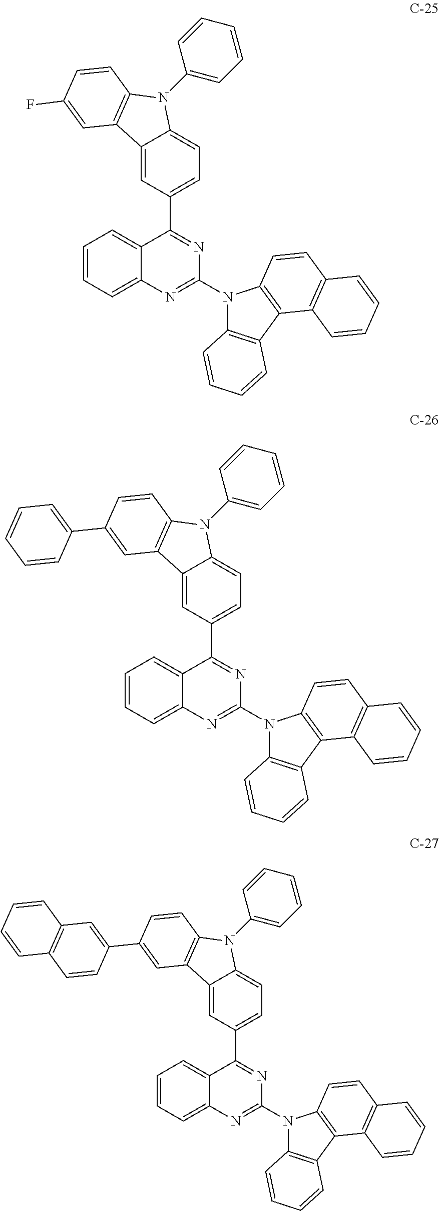 [SMILES: Fc1ccc2c(c1)c1cc(-c3nc(-n4c5ccccc5c5c6ccccc6ccc54)nc4ccccc34)ccc1n2-c1ccccc1 ; c1ccc(-c2ccc3c(c2)c2cc(-c4nc(-n5c6ccccc6c6c7ccccc7ccc65)nc5ccccc45)ccc2n3-c2ccccc2)cc1 ; c1ccc(-n2c3ccc(-c4ccc5ccccc5c4)cc3c3cc(-c4nc(-n5c6ccccc6c6c7ccccc7ccc65)nc5ccccc45)ccc32)cc1]

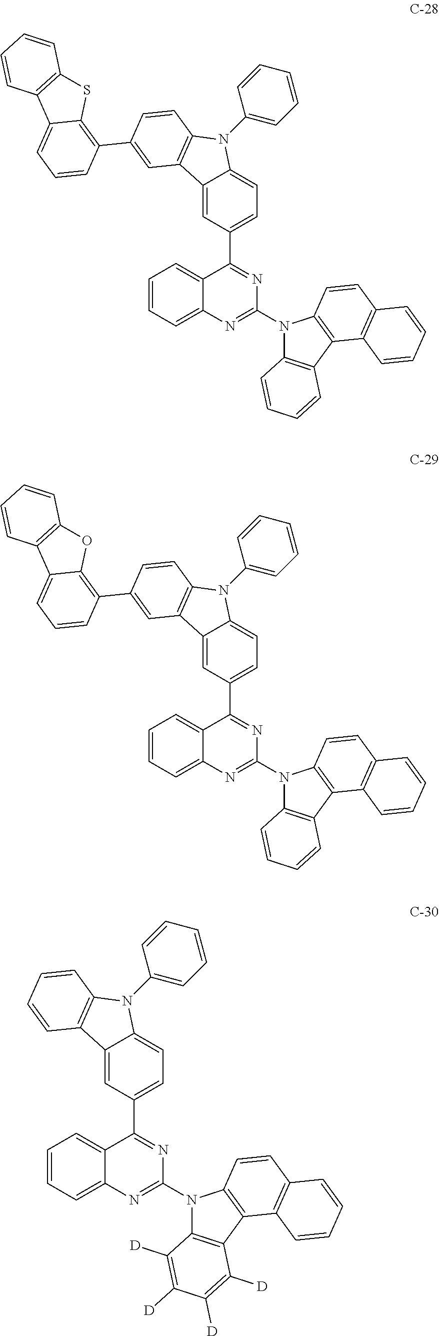 [SMILES: c1ccc(-n2c3ccc(-c4nc(-n5c6ccccc6c6c7ccccc7ccc65)nc5ccccc45)cc3c3cc(-c4cccc5c4sc4ccccc45)ccc32)cc1 ; c1ccc(-n2c3ccc(-c4nc(-n5c6ccccc6c6c7ccccc7ccc65)nc5ccccc45)cc3c3cc(-c4cccc5c4oc4ccccc45)ccc32)cc1 ; [2H]c1c([2H])c([2H])c2c(c1[2H])c1c3ccccc3ccc1n2-c1nc(-c2ccc3c(c2)c2ccccc2n3-c2ccccc2)c2ccccc2n1]

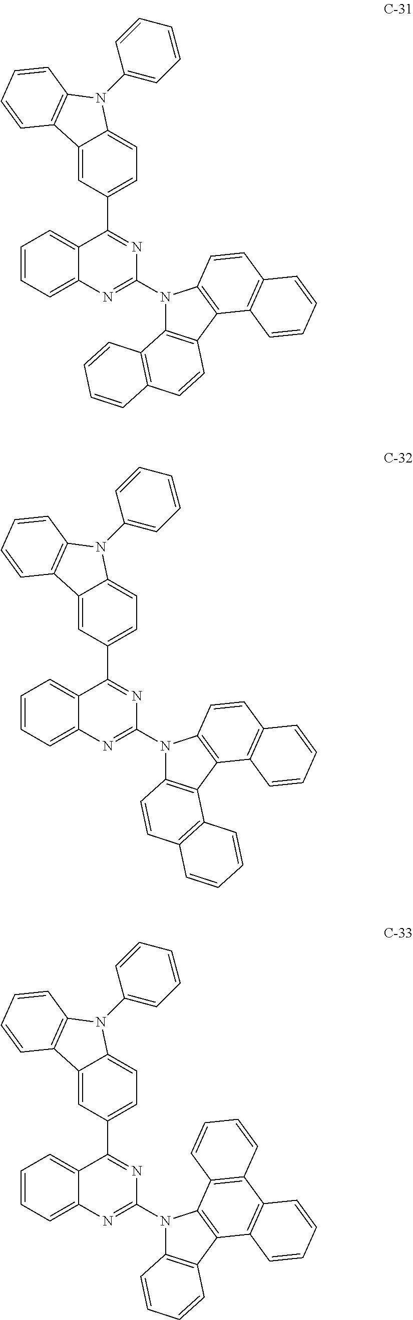 [SMILES: c1ccc(-n2c3ccccc3c3cc(-c4nc(-n5c6ccc7ccccc7c6c6ccc7ccccc7c65)nc5ccccc45)ccc32)cc1 ; c1ccc(-n2c3ccccc3c3cc(-c4nc(-n5c6ccc7ccccc7c6c6c7ccccc7ccc65)nc5ccccc45)ccc32)cc1 ; c1ccc(-n2c3ccccc3c3cc(-c4nc(-n5c6ccccc6c6c7ccccc7c7ccccc7c65)nc5ccccc45)ccc32)cc1]

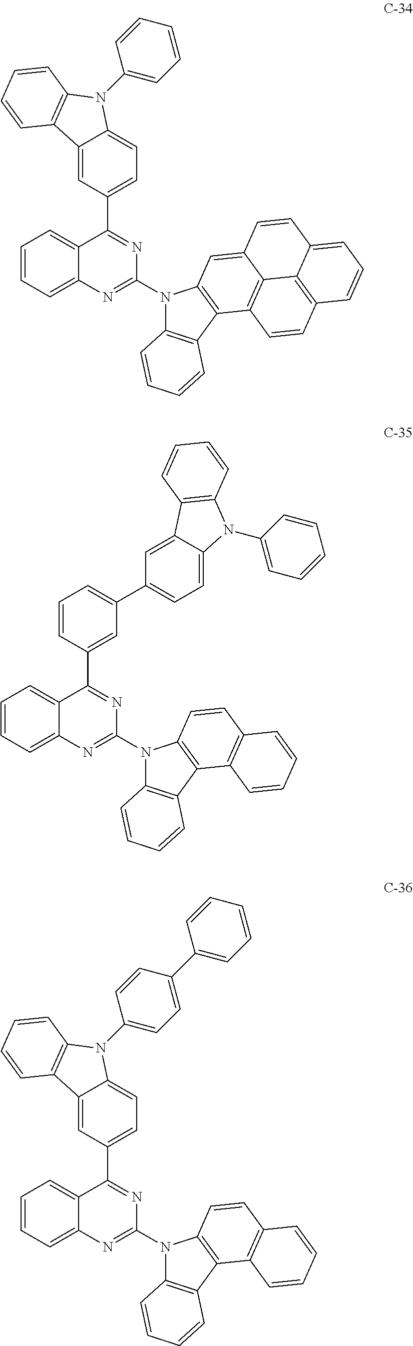 [SMILES: c1ccc(-n2c3ccccc3c3cc(-c4nc(-n5c6ccccc6c6c7ccc8cccc9ccc(cc65)c7c98)nc5ccccc45)ccc32)cc1 ; c1ccc(-n2c3ccccc3c3cc(-c4cccc(-c5nc(-n6c7ccccc7c7c8ccccc8ccc76)nc6ccccc56)c4)ccc32)cc1 ; c1ccc(-c2ccc(-n3c4ccccc4c4cc(-c5nc(-n6c7ccccc7c7c8ccccc8ccc76)nc6ccccc56)ccc43)cc2)cc1]

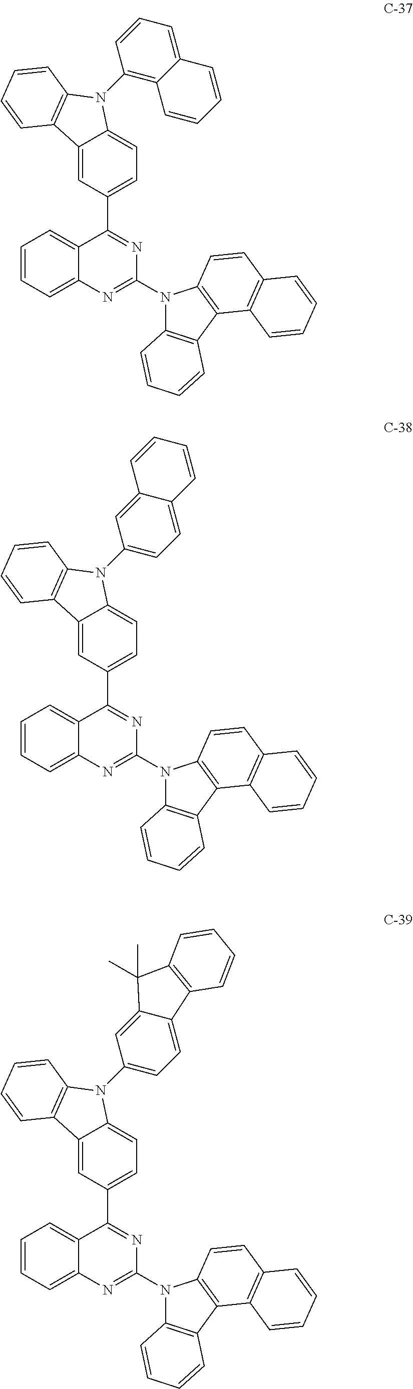 [SMILES: c1ccc2c(-n3c4ccccc4c4cc(-c5nc(-n6c7ccccc7c7c8ccccc8ccc76)nc6ccccc56)ccc43)cccc2c1 ; c1ccc2cc(-n3c4ccccc4c4cc(-c5nc(-n6c7ccccc7c7c8ccccc8ccc76)nc6ccccc56)ccc43)ccc2c1 ; CC1(C)c2ccccc2-c2ccc(-n3c4ccccc4c4cc(-c5nc(-n6c7ccccc7c7c8ccccc8ccc76)nc6ccccc56)ccc43)cc21]

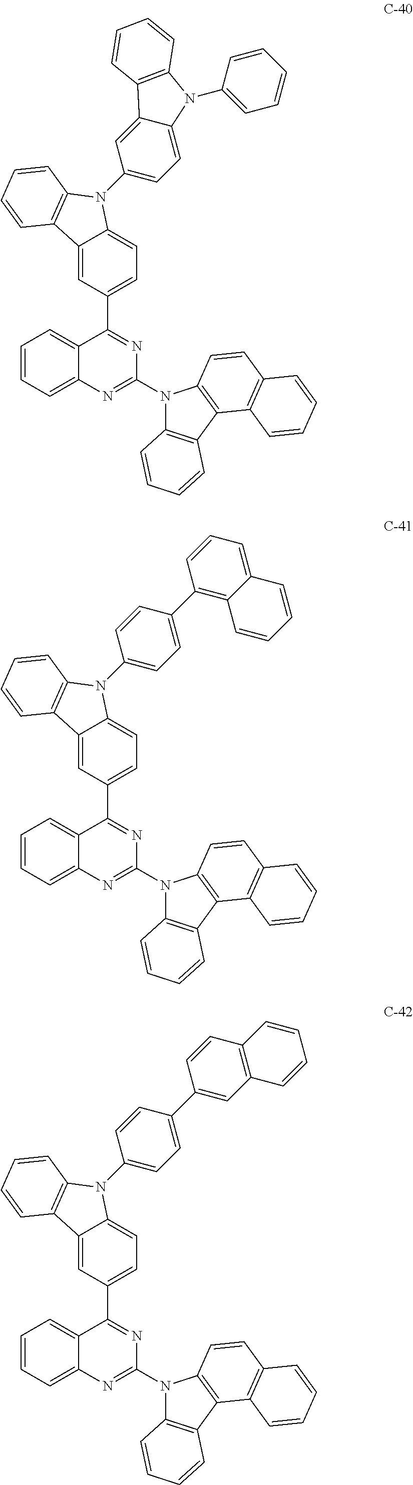 [SMILES: c1ccc(-n2c3ccccc3c3cc(-n4c5ccccc5c5cc(-c6nc(-n7c8ccccc8c8c9ccccc9ccc87)nc7ccccc67)ccc54)ccc32)cc1 ; c1ccc2c(-c3ccc(-n4c5ccccc5c5cc(-c6nc(-n7c8ccccc8c8c9ccccc9ccc87)nc7ccccc67)ccc54)cc3)cccc2c1 ; c1ccc2cc(-c3ccc(-n4c5ccccc5c5cc(-c6nc(-n7c8ccccc8c8c9ccccc9ccc87)nc7ccccc67)ccc54)cc3)ccc2c1]

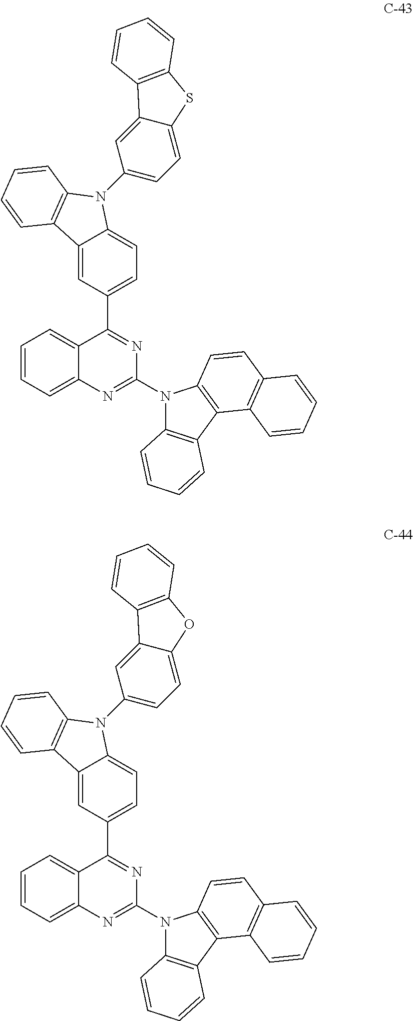 [SMILES: c1ccc2c(c1)ccc1c2c2ccccc2n1-c1nc(-c2ccc3c(c2)c2ccccc2n3-c2ccc3sc4ccccc4c3c2)c2ccccc2n1 ; c1ccc2c(c1)ccc1c2c2ccccc2n1-c1nc(-c2ccc3c(c2)c2ccccc2n3-c2ccc3oc4ccccc4c3c2)c2ccccc2n1]

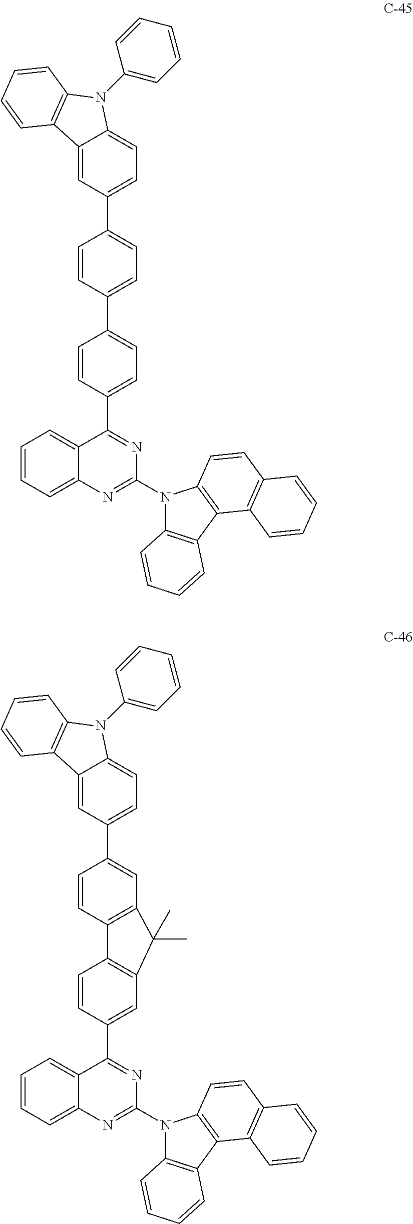 [SMILES: c1ccc(-n2c3ccccc3c3cc(-c4ccc(-c5ccc(-c6nc(-n7c8ccccc8c8c9ccccc9ccc87)nc7ccccc67)cc5)cc4)ccc32)cc1 ; CC1(C)c2cc(-c3ccc4c(c3)c3ccccc3n4-c3ccccc3)ccc2-c2ccc(-c3nc(-n4c5ccccc5c5c6ccccc6ccc54)nc4ccccc34)cc21]

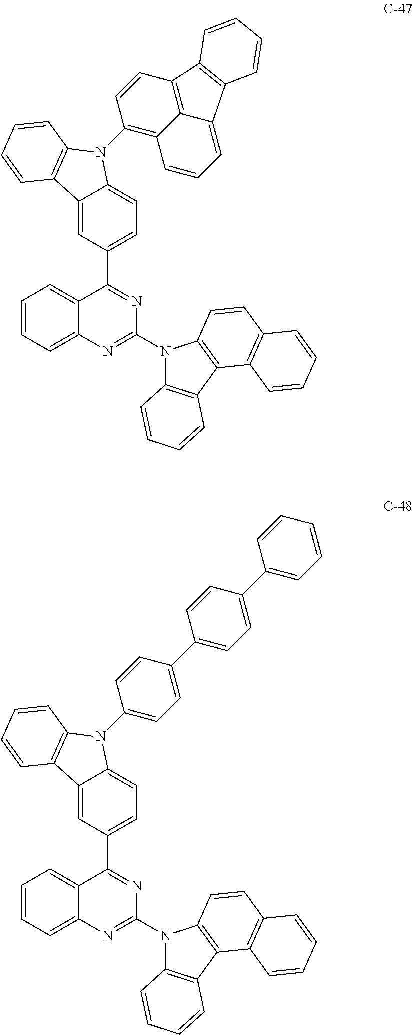 [SMILES: c1ccc2c(c1)-c1cccc3c(-n4c5ccccc5c5cc(-c6nc(-n7c8ccccc8c8c9ccccc9ccc87)nc7ccccc67)ccc54)ccc-2c13 ; c1ccc(-c2ccc(-c3ccc(-n4c5ccccc5c5cc(-c6nc(-n7c8ccccc8c8c9ccccc9ccc87)nc7ccccc67)ccc54)cc3)cc2)cc1]

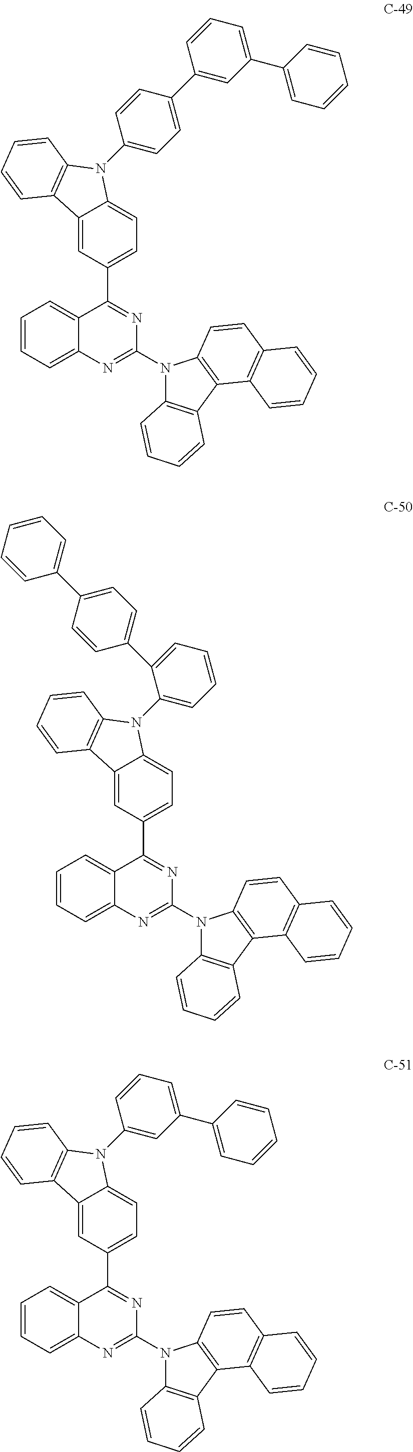 [SMILES: c1ccc(-c2cccc(-c3ccc(-n4c5ccccc5c5cc(-c6nc(-n7c8ccccc8c8c9ccccc9ccc87)nc7ccccc67)ccc54)cc3)c2)cc1 ; c1ccc(-c2ccc(-c3ccccc3-n3c4ccccc4c4cc(-c5nc(-n6c7ccccc7c7c8ccccc8ccc76)nc6ccccc56)ccc43)cc2)cc1 ; c1ccc(-c2cccc(-n3c4ccccc4c4cc(-c5nc(-n6c7ccccc7c7c8ccccc8ccc76)nc6ccccc56)ccc43)c2)cc1]

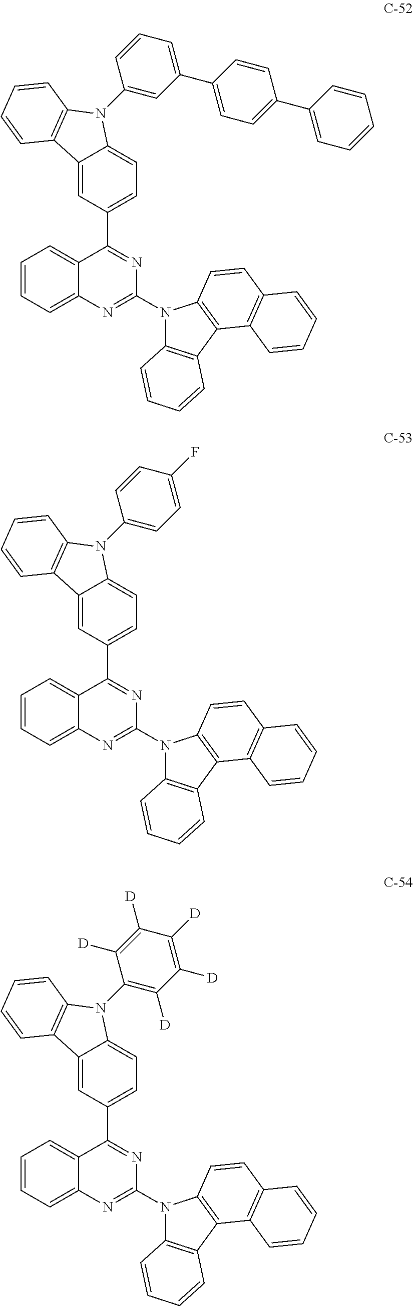

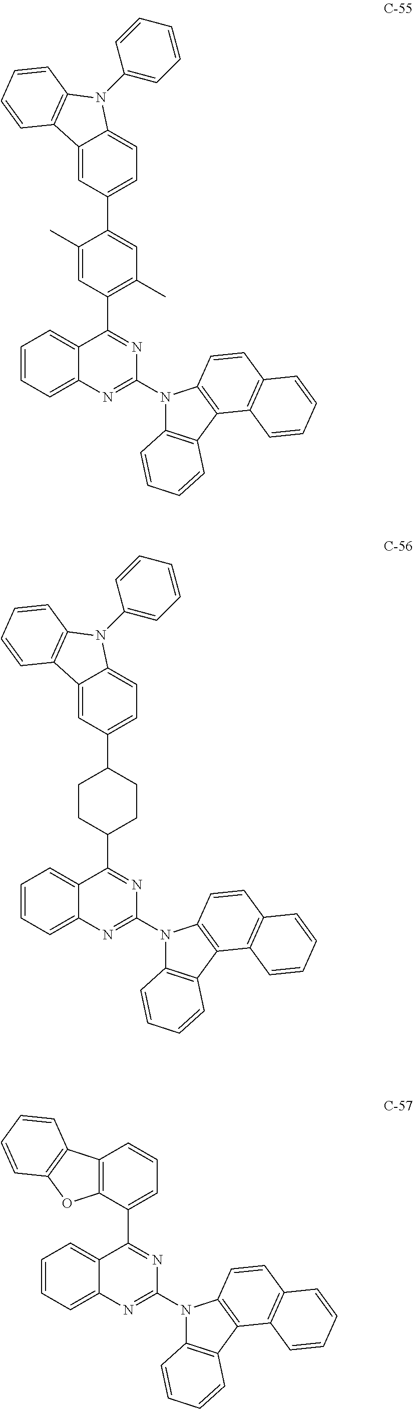 [SMILES: Cc1cc(-c2nc(-n3c4ccccc4c4c5ccccc5ccc43)nc3ccccc23)c(C)cc1-c1ccc2c(c1)c1ccccc1n2-c1ccccc1 ; c1ccc(-n2c3ccccc3c3cc(C4CCC(c5nc(-n6c7ccccc7c7c8ccccc8ccc76)nc6ccccc56)CC4)ccc32)cc1 ; c1ccc2c(c1)ccc1c2c2ccccc2n1-c1nc(-c2cccc3c2oc2ccccc23)c2ccccc2n1]

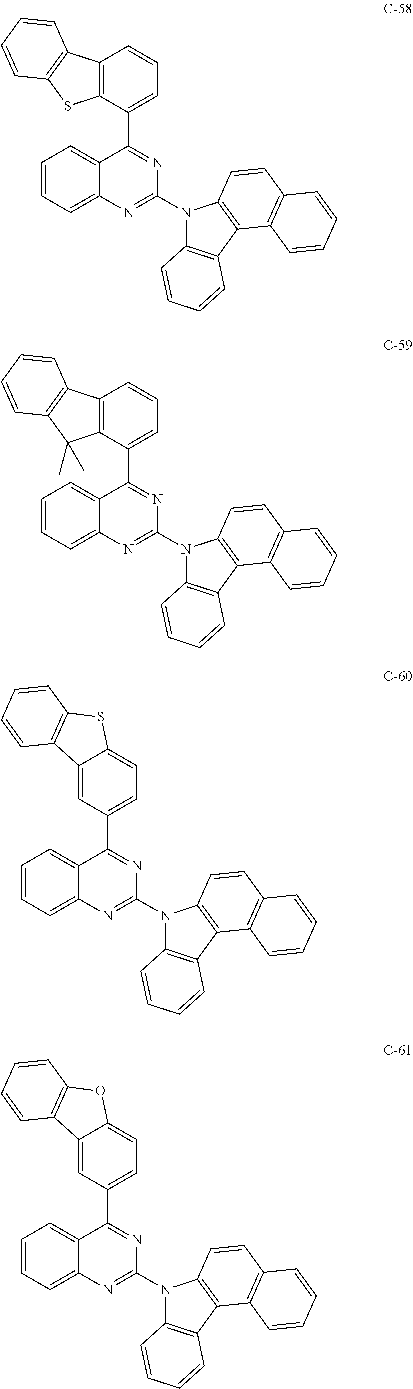 [SMILES: c1ccc2c(c1)ccc1c2c2ccccc2n1-c1nc(-c2cccc3c2sc2ccccc23)c2ccccc2n1 ; CC1(C)c2ccccc2-c2cccc(-c3nc(-n4c5ccccc5c5c6ccccc6ccc54)nc4ccccc34)c21 ; c1ccc2c(c1)ccc1c2c2ccccc2n1-c1nc(-c2ccc3sc4ccccc4c3c2)c2ccccc2n1 ; c1ccc2c(c1)ccc1c2c2ccccc2n1-c1nc(-c2ccc3oc4ccccc4c3c2)c2ccccc2n1]

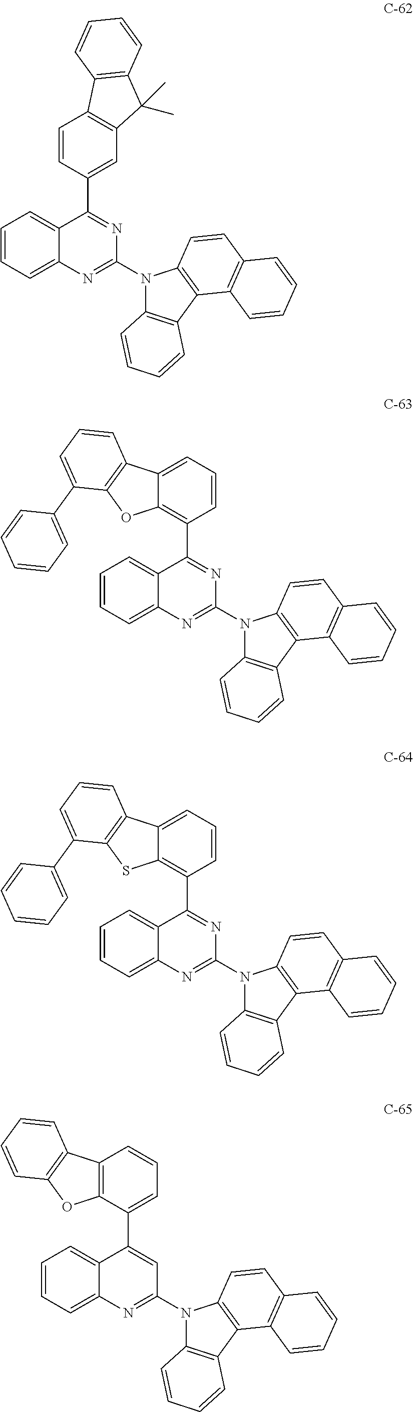 [SMILES: CC1(C)c2ccccc2-c2ccc(-c3nc(-n4c5ccccc5c5c6ccccc6ccc54)nc4ccccc34)cc21 ; c1ccc(-c2cccc3c2oc2c(-c4nc(-n5c6ccccc6c6c7ccccc7ccc65)nc5ccccc45)cccc23)cc1 ; c1ccc(-c2cccc3c2sc2c(-c4nc(-n5c6ccccc6c6c7ccccc7ccc65)nc5ccccc45)cccc23)cc1 ; c1ccc2c(c1)ccc1c2c2ccccc2n1-c1cc(-c2cccc3c2oc2ccccc23)c2ccccc2n1]

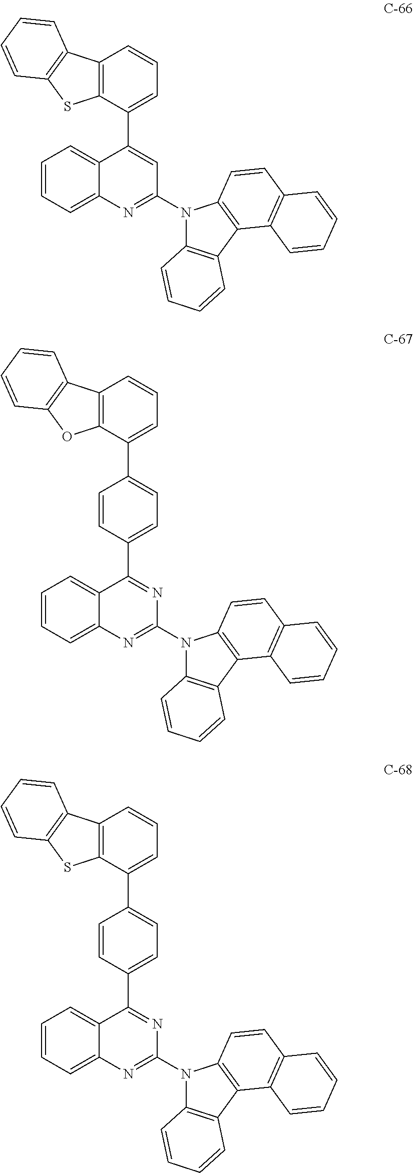 [SMILES: c1ccc2c(c1)ccc1c2c2ccccc2n1-c1cc(-c2cccc3c2sc2ccccc23)c2ccccc2n1 ; c1ccc2c(c1)ccc1c2c2ccccc2n1-c1nc(-c2ccc(-c3cccc4c3oc3ccccc34)cc2)c2ccccc2n1 ; c1ccc2c(c1)ccc1c2c2ccccc2n1-c1nc(-c2ccc(-c3cccc4c3sc3ccccc34)cc2)c2ccccc2n1]

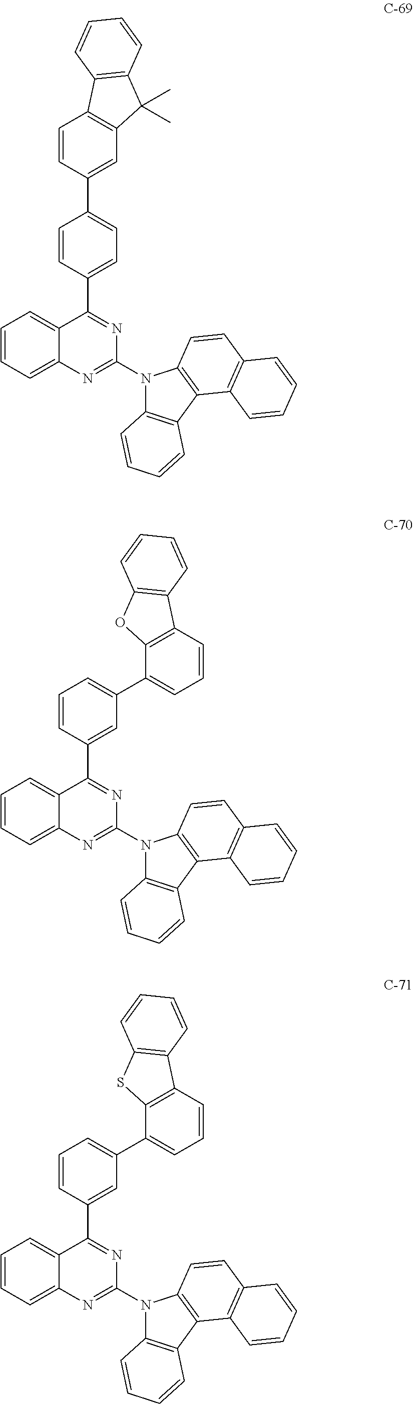 [SMILES: CC1(C)c2ccccc2-c2ccc(-c3ccc(-c4nc(-n5c6ccccc6c6c7ccccc7ccc65)nc5ccccc45)cc3)cc21 ; c1cc(-c2nc(-n3c4ccccc4c4c5ccccc5ccc43)nc3ccccc23)cc(-c2cccc3c2oc2ccccc23)c1 ; c1cc(-c2nc(-n3c4ccccc4c4c5ccccc5ccc43)nc3ccccc23)cc(-c2cccc3c2sc2ccccc23)c1]

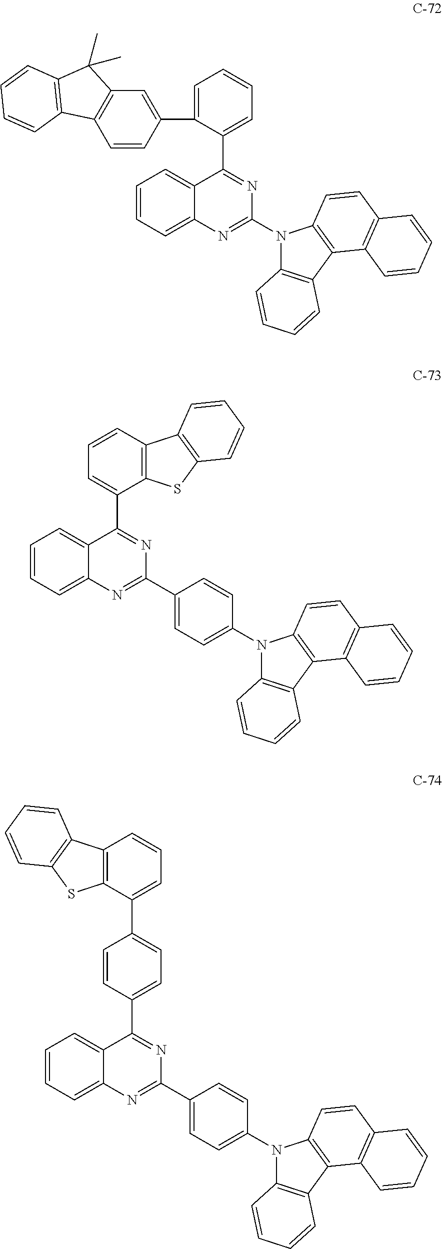 [SMILES: CC1(C)c2ccccc2-c2ccc(-c3ccccc3-c3nc(-n4c5ccccc5c5c6ccccc6ccc54)nc4ccccc34)cc21 ; c1ccc2c(c1)ccc1c2c2ccccc2n1-c1ccc(-c2nc(-c3cccc4c3sc3ccccc34)c3ccccc3n2)cc1 ; c1ccc2c(c1)ccc1c2c2ccccc2n1-c1ccc(-c2nc(-c3ccc(-c4cccc5c4sc4ccccc45)cc3)c3ccccc3n2)cc1]

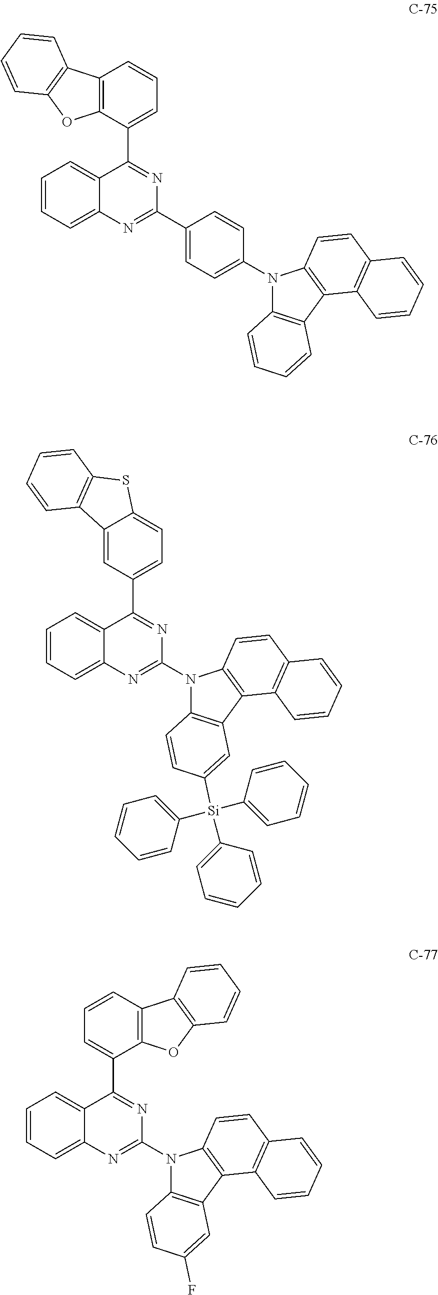 [SMILES: c1ccc2c(c1)ccc1c2c2ccccc2n1-c1ccc(-c2nc(-c3cccc4c3oc3ccccc34)c3ccccc3n2)cc1 ; c1ccc([Si](c2ccccc2)(c2ccccc2)c2ccc3c(c2)c2c4ccccc4ccc2n3-c2nc(-c3ccc4sc5ccccc5c4c3)c3ccccc3n2)cc1 ; Fc1ccc2c(c1)c1c3ccccc3ccc1n2-c1nc(-c2cccc3c2oc2ccccc23)c2ccccc2n1]

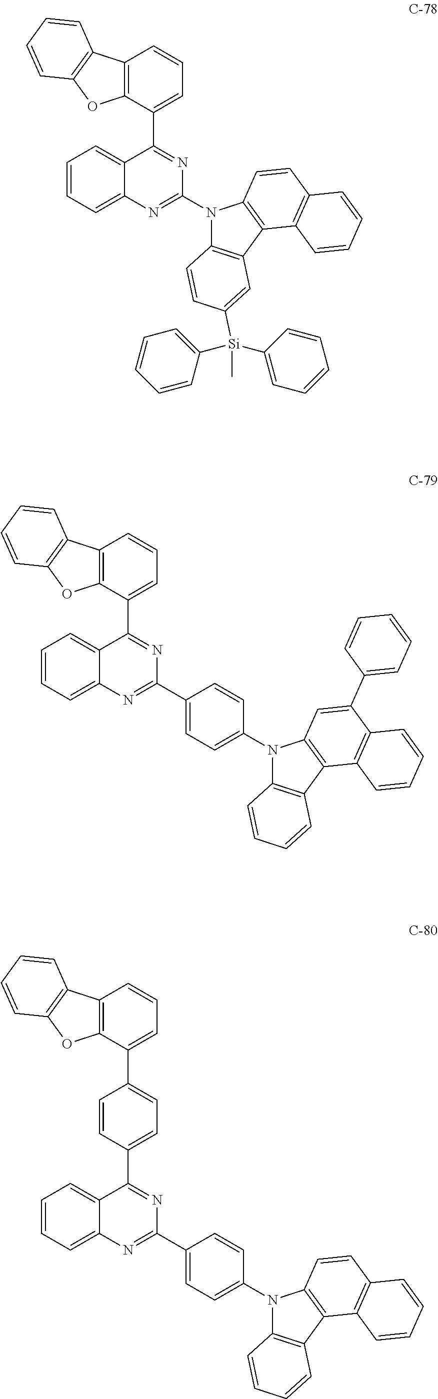 [SMILES: C[Si](c1ccccc1)(c1ccccc1)c1ccc2c(c1)c1c3ccccc3ccc1n2-c1nc(-c2cccc3c2oc2ccccc23)c2ccccc2n1 ; c1ccc(-c2cc3c(c4ccccc24)c2ccccc2n3-c2ccc(-c3nc(-c4cccc5c4oc4ccccc45)c4ccccc4n3)cc2)cc1 ; c1ccc2c(c1)ccc1c2c2ccccc2n1-c1ccc(-c2nc(-c3ccc(-c4cccc5c4oc4ccccc45)cc3)c3ccccc3n2)cc1]

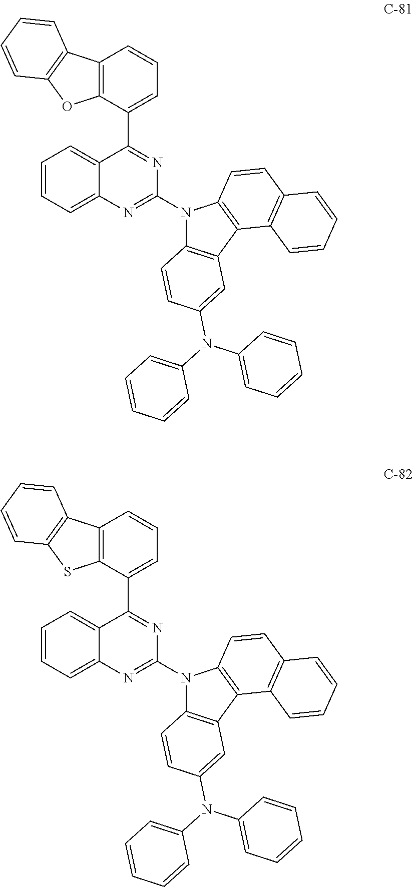 [SMILES: c1ccc(N(c2ccccc2)c2ccc3c(c2)c2c4ccccc4ccc2n3-c2nc(-c3cccc4c3oc3ccccc34)c3ccccc3n2)cc1 ; c1ccc(N(c2ccccc2)c2ccc3c(c2)c2c4ccccc4ccc2n3-c2nc(-c3cccc4c3sc3ccccc34)c3ccccc3n2)cc1]

6. An organic electroluminescent device comprising the compound according to claim 1.
